(19) United States
(12) Patent Application Publication
(10) Pub. No.: US 2026/0165058 A1
(43) Pub. Date: Jun. 11, 2026

(54) METHOD FOR MANUFACTURING SEMICONDUCTOR SUBSTRATE AND COMPOSITION

(71) Applicant: JSR CORPORATION, Tokyo (JP)

(72) Inventors: Takashi TSUJI, Tokyo (JP); Hiroki NAKATSU, Tokyo (JP); Takashi KATAGIRI, Tokyo (JP); Shinya ABE, Tokyo (JP); Atsuko NAGANAWA, Tokyo (JP)

(73) Assignee: JSR CORPORATION, Tokyo (JP)

(21) Appl. No.: 19/180,259

(22) Filed: Apr. 16, 2025

Related U.S. Application Data
(63) Continuation-in-part of application No. PCT/JP2023/036847, filed on Oct. 11, 2023.

(30) Foreign Application Priority Data
Oct. 18, 2022 (JP) 2022-166619

(51) Int. Cl. H10P 50/00; G03F 7/11; H10P 50/24; H10P 50/28

(52) U.S. Cl. CPC H10P 50/692; G03F 7/11; H10P 50/242; H10P 50/283; H10P 50/73

(57) ABSTRACT

A method for manufacturing a semiconductor substrate includes: forming a resist underlayer film directly or indirectly on a substrate by applying a composition for forming a resist underlayer film; forming a resist pattern directly or indirectly on the resist underlayer film; and performing etching using the resist pattern as a mask. The composition includes: a compound including a nitro group; and a solvent. The compound is a polymer including a repeating unit which includes a nitro group and an aromatic ring, an aromatic ring-containing compound including a nitro group and an aromatic ring, and having a molecular weight of 600 or more and 3,000 or less, or a combination thereof. A content of the compound in the composition relative to total components other than the solvent in the composition is 10% by mass or more.

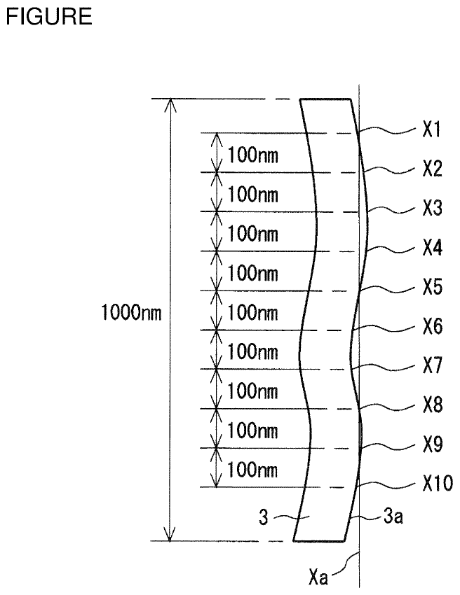

### CROSS-REFERENCE TO RELATED APPLICATIONS

The present application is a continuation-in-part application of International Patent Application No. PCT/JP2023/036847 filed Oct. 11, 2023, which claims priority to Japanese Patent Application No. 2022-166619 filed Oct. 18, 2022. The contents of these applications are incorporated herein by reference in their entirety.

### BACKGROUND OF THE DISCLOSURE

### Technical Field

The present disclosure relates to and a method for manufacturing a semiconductor substrate and a composition.

### Background Art

A semiconductor device is produced using, for example, a multilayer resist process in which a resist pattern is formed by exposing and developing a resist film laminated on a substrate with a resist underlayer film, such as an organic underlayer film or a silicon-containing film, being interposed between them. In this process, the resist underlayer film is etched using this resist pattern as a mask, and the substrate is further etched using the obtained resist underlayer film pattern as a mask so that a desired pattern is formed on the semiconductor substrate (see JP-A-2004-177668).

Various studies have been conducted on materials to be used for such a composition for forming a resist underlayer film (see WO 2011/108365 A).

### SUMMARY

According to an aspect of the present disclosure, a method for manufacturing a semiconductor substrate includes: forming a resist underlayer film directly or indirectly on a substrate by applying a composition for forming a resist underlayer film; forming a resist pattern directly or indirectly on the resist underlayer film; and performing etching using the resist pattern as a mask. The composition for forming a resist underlayer film includes: a compound including a nitro group (hereinafter also referred to as a “compound [A]”); and a solvent (hereinafter also referred to as a “solvent [B]”). The compound including a nitro group is a polymer including a repeating unit which includes a nitro group and an aromatic ring (hereinafter also referred to as a “polymer [A1]”), an aromatic ring-containing compound including a nitro group and an aromatic ring, and having a molecular weight of 600 or more and 3,000 or less (hereinafter also referred to as an “aromatic ring-containing compound [A2]”), or a combination thereof. A content of the compound including a nitro group in the composition for forming a resist underlayer film relative to total components other than the solvent in the composition for forming a resist underlayer film is 10% by mass or more.

According to another aspect of the present disclosure, a composition includes: a compound including a nitro group; and a solvent. The compound including a nitro group is a polymer including a repeating unit which includes a nitro group and an aromatic ring, an aromatic ring-containing compound including a nitro group and an aromatic ring, and having a molecular weight of 600 or more and 3,000 or less, or a combination thereof. A content ratio of the compound including a nitro group in the composition relative to total components other than the solvent in the composition is 10% by mass or more.

### BRIEF DESCRIPTION OF THE DRAWINGS

FIGURE is a schematic plan view for explaining a method of evaluating bending resistance.

### DESCRIPTION OF THE EMBODIMENTS

As used herein, the words “a” and “an” and the like carry the meaning of “one or more.” When an amount, concentration, or other value or parameter is given as a range, and/or its description includes a list of upper and lower values, this is to be understood as specifically disclosing all integers and fractions within the given range, and all ranges formed from any pair of any upper and lower values, regardless of whether subranges are separately disclosed. Where a range of numerical values is recited herein, unless otherwise stated, the range is intended to include the endpoints thereof, as well as all integers and fractions within the range. As an example, a stated range of 1-10 fully describes and includes the independent subrange 3.4-7.2 as does the following list of values: 1, 4, 6, 10.

In a multilayer resist process, an organic underlayer film as a resist underlayer film is required to exhibit bending resistance and solubility during liquid discharge from the semiconductor manufacturing equipment.

According to the method for manufacturing a semiconductor substrate, since a resist underlayer film excellent in bending resistance and solubility during liquid discharge is formed, a semiconductor substrate having a favorable pattern can be obtained with a high yield. According to the composition, a film excellent in bending resistance and solubility during liquid discharge can be formed. Therefore, they can suitably be used for, for example, producing semiconductor devices expected to be further microfabricated in the future.

Hereinafter, a method for manufacturing a semiconductor substrate and a composition according to embodiments of the present disclosure will be described in detail. Combinations of suitable modes in embodiments are also preferred.

### <<Method for Manufacturing Semiconductor Substrate>>

The method for manufacturing a semiconductor substrate includes: applying a composition for forming a resist underlayer film directly or indirectly to a substrate (hereinafter also referred to as an “applying step”); forming a resist pattern directly or indirectly on the resist underlayer film formed by applying the composition for forming a resist underlayer film (hereinafter also referred to as a “resist pattern forming step”); and performing etching using the resist pattern as a mask (hereinafter also referred to as an “etching step”).

According to the method for manufacturing a semiconductor substrate, a resist underlayer film superior in etching resistance, heat resistance, and bending resistance can be formed due to the use of the composition described later as a composition for forming a resist underlayer film in the applying step, so that a semiconductor substrate having a favorable pattern configuration can be manufactured.

The method for manufacturing a semiconductor substrate may further include, as necessary, a step of forming a silicon-containing film directly or indirectly on the resist underlayer film before the formation of the resist pattern (hereinafter also referred to as “silicon-containing film forming step”).

Hereinafter, the composition to be used in the method for manufacturing a semiconductor substrate and the respective steps will be described.

### <<Composition>>

The composition as a composition for forming a resist underlayer film contains a compound [A] and a solvent [B]. The composition may include an optional component as long as the effect of the composition is not impaired.

As the composition contains the compound [A] and the solvent [B], a film excellent in bending resistance and solubility during liquid discharge can be formed. Accordingly, the composition can be used as a composition for forming a film. Specifically, the composition can be suitably used a composition for forming a resist underlayer film in a multilayer resist process.

Each component contained in the composition will be described below.

### <Compound [A]>

The compound [A] is a compound having a nitro group, and is a polymer [A1], an aromatic ring-containing compound [A2] (however, excluding compounds corresponding to the polymer [A1]), or a combination thereof. Each of the polymer [A1] and the aromatic ring-containing compound [A2] may be used singly or in combination of two or more kinds thereof.

### (Polymer [A1])

As the polymer [A1] as the compound [A], known polymers used for the formation of resist underlayer films can be suitably used as long as they have a repeating unit containing a nitro group and an aromatic ring. Among these, novolac polymers are preferred from the viewpoint of the heat resistance and high rigidity of the film to be obtained.

As the aromatic ring included in the polymer [A1], an aromatic ring having 5 to 40 ring atoms is preferable, examples of the aromatic ring include aromatic hydrocarbon rings such as a benzene ring, a naphthalene ring, an anthracene ring, a phenalene ring, a phenanthrene ring, a pyrene ring, a fluorene ring, a perylene ring, and a coronene ring; aromatic heterocycles such as a furan ring, a pyrrole ring, a thiophene ring, a phosphole ring, a pyrazole ring, an oxazole ring, an isoxazole ring, a thiazole ring, a pyridine ring, a pyrazine ring, a pyrimidine ring, a pyridazine ring, and a triazine group, or combinations thereof. The aromatic ring of the Ar¹ is preferably at least one aromatic hydrocarbon ring selected from the group consisting of a benzene ring, a naphthalene ring, an anthracene ring, a phenalene ring, a phenanthrene ring, a pyrene ring, a fluorene ring and a perylene ring.

In the present specification, the term “ring members” refers to the number of atoms constituting the ring. For example, a biphenyl ring has 12 ring members, a naphthalene ring has 10 ring members, and a fluorene ring has 13 ring members. The term “polycyclic condensed aromatic ring” refers to a polycyclic aromatic hydrocarbon composed of a plurality of aromatic rings sharing a side (a bond between two adjacent carbon atoms).

The polymer [A1] is preferably a polymer having a repeating unit represented by formula (1). The polymer [A1] may have two or more kinds of repeating units represented by formula (1).

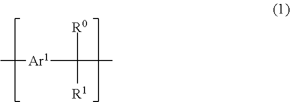

in the formula (1), Ar¹ is a divalent group having an aromatic ring having 5 to 40 ring atoms; and R⁰ is a hydrogen atom or a monovalent organic group having 1 to 40 carbon atoms, R¹ is a monovalent organic group having 1 to 40 carbon atoms, or R⁰ and R¹ are bonded to each other to form a ring structure, and at least one selected from the group consisting of Ar¹, R⁰ and R¹ has a nitro group).

In the polymer [A], at least one selected from the group consisting of Ar¹, R⁰ and R¹ has a nitro group. It is preferred that at least one selected from the group consisting of Ar¹ and R¹ has a nitro group, and it is more preferred that R¹ has a nitro group. The highly polar nitro group induces proximity attracting action between polymer chains, and the crosslinking reaction of the polymer [A1] can be promoted and the bending resistance can be improved. The introduction of a nitro group can also improve solubility in highly polar effluents. These effects can be attained in both the main chain moiety and the side chain moiety, and can be achieved at a higher level by introducing a nitro group into the side chain moiety having a high degree of freedom.

In the formula (1), suitable examples of the divalent group having an aromatic ring having 5 to 40 ring members, represented by Ar¹ include a group obtained by removing two hydrogen atoms from the aromatic ring having 5 to 40 ring members, which is suitably contained in the polymer [A], or a combination of the aromatic ring with a chain structure. In a case where aromatic rings are combined, the aromatic rings may be bonded to each other via a single bond in addition to a condensed ring structure.

As the chain structure, a chain hydrocarbon having 1 to 20 carbon atoms can be suitably adopted. Examples of the chain hydrocarbon having 1 to 20 carbon atoms include methane, ethane, propane, butane, hexane, and octane. These may be either linear or branched. Among these, a linear or branched alkane having 1 to 8 carbon atoms is preferred.

In the formula (1), examples of the monovalent organic group having 1 to 40 carbon atoms represented by R⁰ and R¹ include a monovalent hydrocarbon group having 1 to 20 carbon atoms, a group containing a divalent heteroatom-containing group between two carbon atoms of this hydrocarbon group or at the end of the hydrocarbon group, a group obtained by substituting some or all of the hydrogen atoms of the hydrocarbon group with a monovalent heteroatom-containing group, and a combination thereof.

Examples of the monovalent hydrocarbon group having 1 to 20 carbon atoms include a monovalent chain hydrocarbon group having 1 to 20 carbon atoms, a monovalent alicyclic hydrocarbon group having 3 to 20 carbon atoms, a monovalent aromatic hydrocarbon group having 6 to 20 carbon atoms, and a combination thereof.

As used herein, the “hydrocarbon group” includes a chain hydrocarbon group, an alicyclic hydrocarbon group, and an aromatic hydrocarbon group. The “hydrocarbon group” includes a saturated hydrocarbon group and an unsaturated hydrocarbon group. The “chain hydrocarbon group” means a hydrocarbon group that contains no cyclic structure and is composed only of a chain structure, and includes both a linear hydrocarbon group and a branched hydrocarbon group. The “alicyclic hydrocarbon group” means a hydrocarbon group that contains only an alicyclic structure as a ring structure and contains no aromatic ring structure, and includes both a monocyclic alicyclic hydrocarbon group and a polycyclic alicyclic hydrocarbon group (however, the alicyclic hydrocarbon group is not required to be composed of only an alicyclic structure, and may contain a chain structure as a part thereof). The “aromatic hydrocarbon group” means a hydrocarbon group containing an aromatic ring structure as a ring structure (however, the aromatic hydrocarbon group is not required to be composed of only an aromatic ring structure, and may contain an alicyclic structure or a chain structure as a part thereof).

Examples of the monovalent chain hydrocarbon group having 1 to 20 carbon atoms include alkyl groups such as a methyl group, an ethyl group, a n-propyl group, an i-propyl group, a n-butyl group, a sec-butyl group, a tert-butyl group; alkenyl groups such as an ethenyl group, a propenyl group and a butenyl group; and alkynyl groups such as an ethynyl group, a propynyl group and a butynyl group.

Examples of the monovalent alicyclic hydrocarbon group having 3 to 20 carbon atoms include cycloalkyl groups such as a cyclopropyl group, a cyclobutyl group, a cyclopentyl group, and a cyclohexyl group; cycloalkenyl groups such as a cyclopropenyl group, a cyclopentenyl group, and a cyclohexenyl group; bridged cyclic saturated hydrocarbon groups such as a norbornyl group, an adamantyl group, and a tricyclodecyl group; and bridged cyclic unsaturated hydrocarbon groups such as a norbornenyl group and a tricyclodecenyl group.

Examples of the monovalent aromatic hydrocarbon group having 6 to 20 carbon atoms include a phenyl group, a tolyl group, a naphthyl group, an anthracenyl group, and a pyrenyl group.

Examples of heteroatoms that constitute divalent or monovalent heteroatom-containing groups include an oxygen atom, a nitrogen atom, a sulfur atom, a phosphorus atom, a silicon atom, and halogen atoms. Examples of the halogen atoms include a fluorine atom, a chlorine atom, a bromine atom, and a nitro group.

Examples of the divalent heteroatom-containing group include —CO—, —CS—, —NH—, —O—, —S—, —SO—, —SO₂—, or groups obtained by combining them.

Examples of the monovalent heteroatom-containing group include a hydroxy group, a sulfanyl group, a cyano group, a nitro group, and halogen atoms.

In a case where R⁰ and R¹ are not bonded to each other to form a ring structure, R⁰ is preferably a hydrogen atom. In a case where R⁰ and R¹ are bonded to each other to form a ring structure, an aromatic ring having 5 to 40 ring members in Ar¹ can be suitably adopted as the ring structure. The ring structure is preferably a fluorene ring.

R¹ preferably has an aromatic ring having 5 to 40 ring members. As the aromatic ring having 5 to 40 ring members in R¹, an aromatic ring having 5 to 40 ring members in Ar¹ can be suitably adopted. In this case, it is preferred that at least one hydrogen atom of the aromatic ring is substituted with a nitro group. The number of nitro groups on the aromatic ring is preferably an integer from 1 to 4, more preferably an integer from 1 to 3, still more preferably 1 or 2 from the viewpoint of the proximity attracting action and solubility of the polymer [A1], and the like.

The polymer [A1] preferably has at least one group selected from the group consisting of a hydroxy group, a group represented by formula (2-1), and a group represented by formula (2-2) (hereinafter, the group represented by formula (2-1) or the group represented by formula (2-2) will also be referred to as “group (α)”).

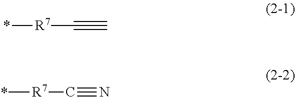

in the formulas (2-1) and (2-2), R⁷ is each independently a divalent organic group having 1 to 20 carbon atoms or a single bond; and * is a bond with a carbon atom in the aromatic ring.

In the formulas (2-1) and (2-2), as the divalent organic group having 1 to 20 carbon atoms represented by R⁷, a group in which one hydrogen atom is removed from the structure corresponding to 1 to 20 carbon atoms among the monovalent organic groups having 1 to 40 carbon atoms represented by R⁰ and R¹ in the formula (1) can be suitably adopted.

A divalent hydrocarbon group having 1 to 10 carbon atoms such as a methanediyl group, an ethanediyl group, and a phenylene group, —O—, and a combination of them are preferable as R⁷, and a methanediyl group or a combination of a methanediyl group and —O— is more preferable.

It is preferred that the polymer [A] as the compound [A] has a group represented by the formula (2-1) and the group is represented by formula (2-1-1) or (2-1-2). In the formula, * has the same meaning as in the formula (2-1).

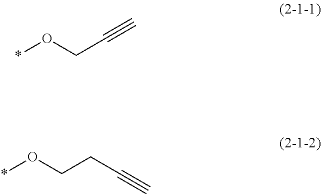

It is preferred that at least one selected from the group consisting of Ar¹, R⁰ and R¹ in the formula (1) preferably has a hydroxy group or the group (α). It is preferred that at least one selected from the group consisting of Ar¹ and R¹ has a hydroxy group or the group (α).

Ar¹, R⁰ and R¹ may have a substituent other than a hydroxy group and the group (α). Examples of the substituent include monovalent chain hydrocarbon groups having 1 to 10 carbon atoms, halogen atoms such as a fluorine atom, a chlorine atom, a bromine atom, and an iodine atom, alkoxy groups such as a methoxy group, an ethoxy group, and a propoxy group, aryloxy groups such as a phenoxy group and a naphthyloxy group, alkoxycarbonyl groups such as a methoxycarbonyl group and an ethoxycarbonyl group, alkoxycarbonyloxy groups such as a methoxycarbonyloxy group and an ethoxycarbonyloxy group, acyl groups such as a formyl group, an acetyl group, a propionyl group, and a butyryl group, a cyano group and a carboxy group.

Examples of the repeating unit (including the repeating unit represented by the formula (1)) that the polymer [A1] may have include repeating units represented by formulas (1-1) to (1-20).

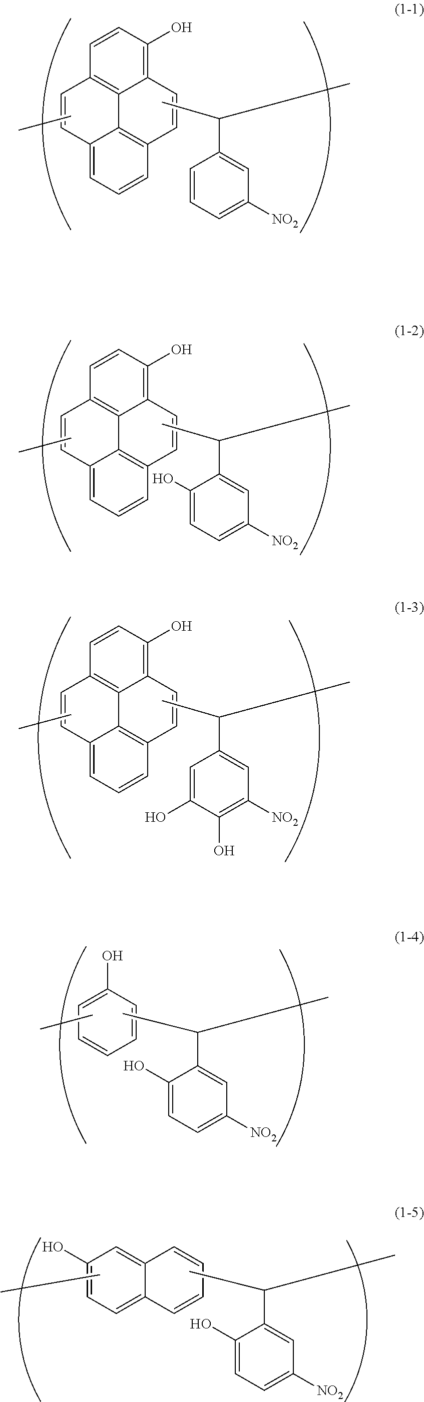

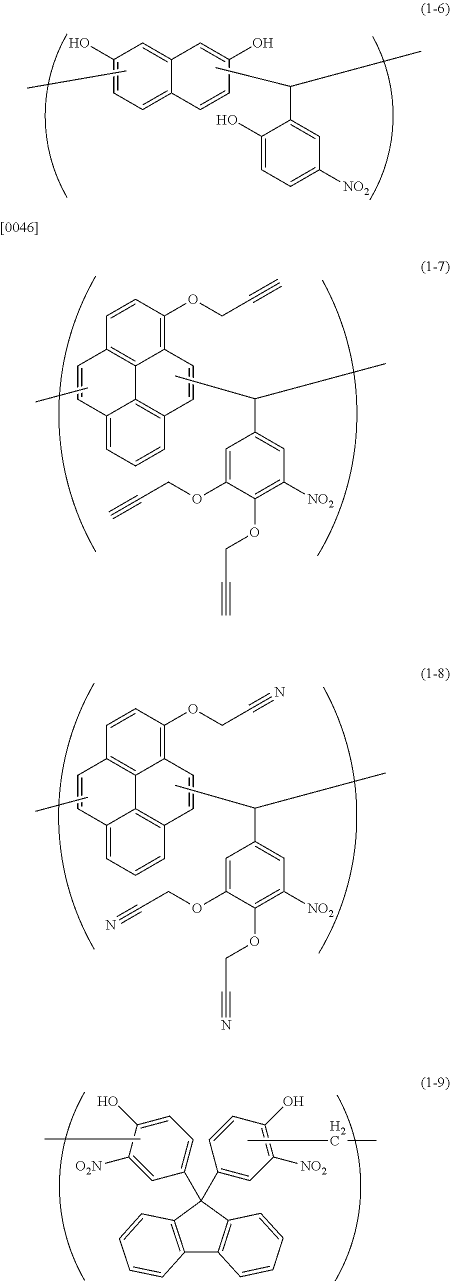

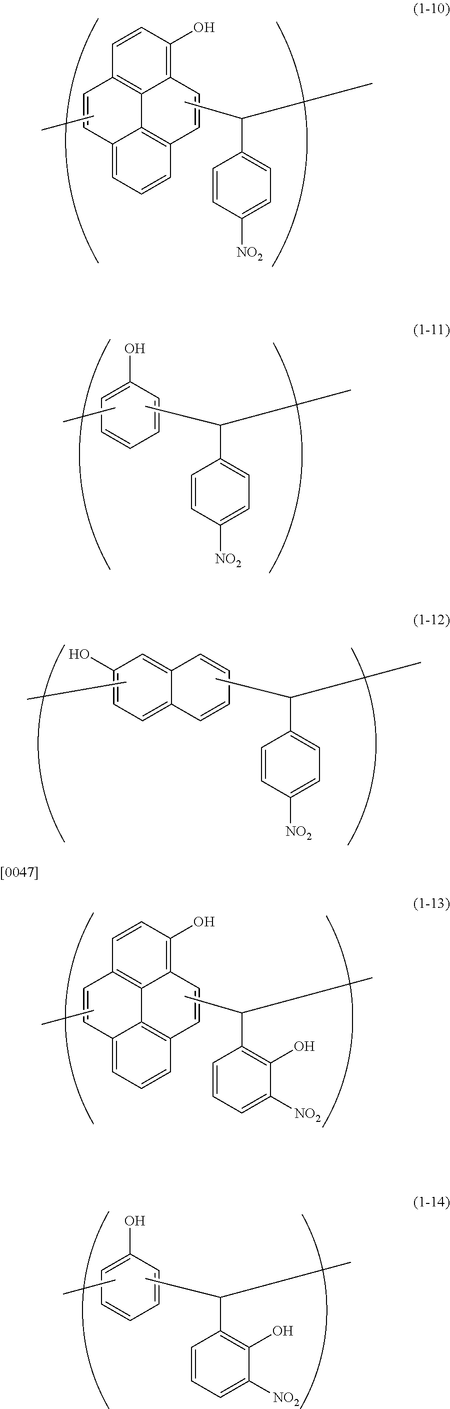

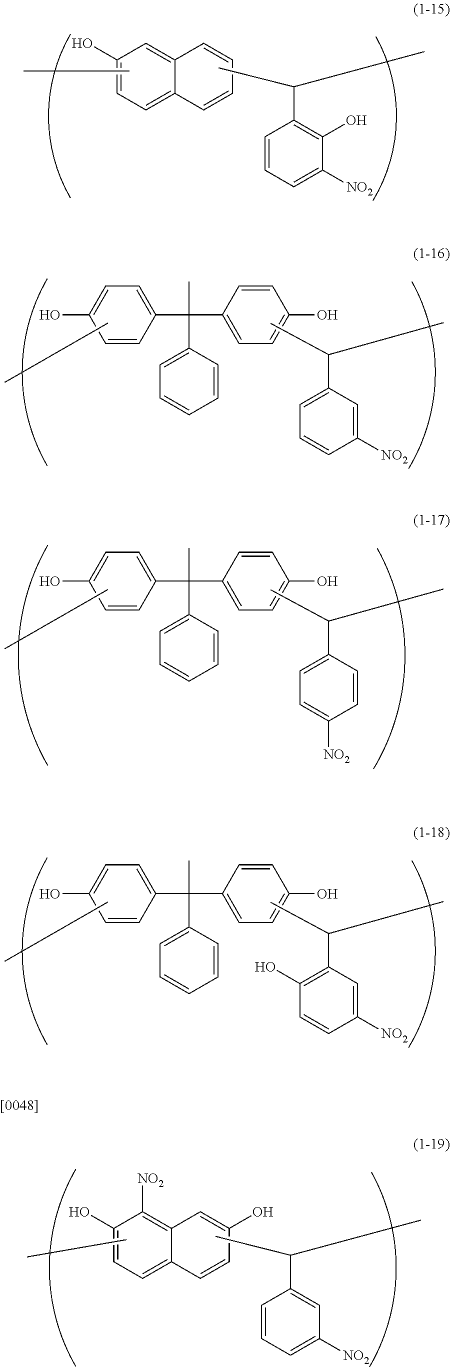

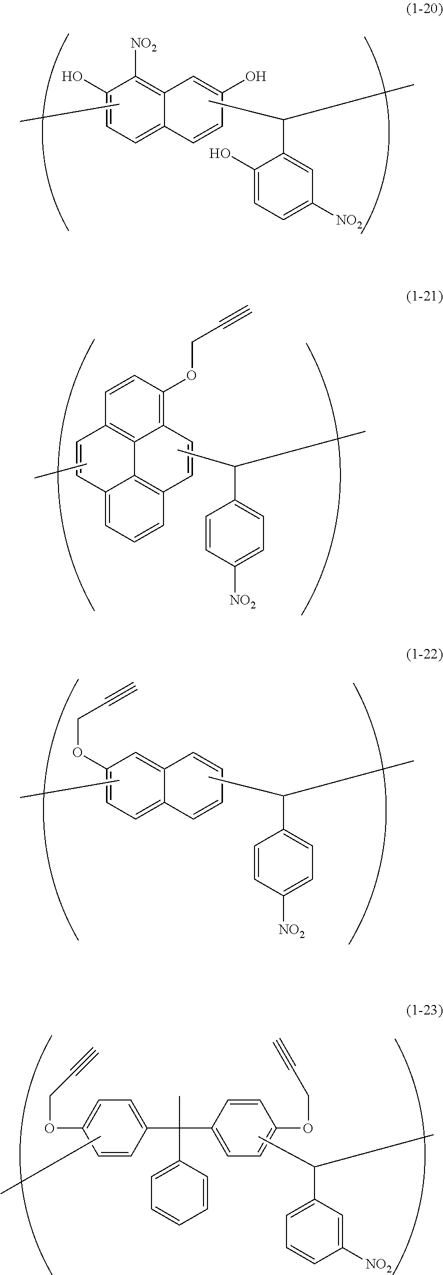

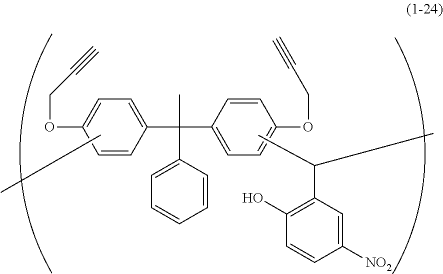

Among these, the repeating units represented by the formulas (1-1) to (1-9) are preferred.

In a case where R⁰ and R¹ in the formula (1) are bonded to each other to form a ring structure, the formula (1) is preferably represented by formula (5).

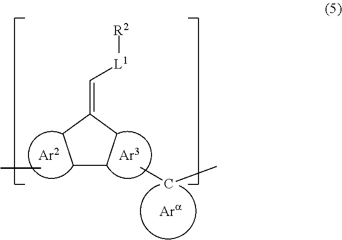

(In the formula (5), Ar² and Ar³ are each independently a substituted or unsubstituted aromatic ring having 5 to 20 ring members that forms a condensed ring structure together with two adjacent carbon atoms in the formula (5), R² is at least one group selected from the group consisting of a substituted or unsubstituted monovalent group containing an aromatic ring having 5 to 60 ring members and a monovalent group containing an aromatic heterocycle having 5 to 20 ring members, L¹ is a single bond or a divalent linking group, Ar^{α} is a divalent group containing an aromatic ring having 5 to 60 ring members, and at least one selected from the group consisting of Ar², Ar³, R², Ar^{α}, and L¹ has a nitro group).

In the formula (5), as the aromatic ring having 5 to 20 ring members in Ar² and Ar³, aromatic rings corresponding to 5 to 20 ring members among the aromatic rings having 5 to 40 ring members in Ar¹ of the formula (1) can be suitably adopted.

As the substituent in the case where Ar² and Ar³ have a substituent other than a nitro group, a hydroxy group, the group (α), and the substituents mentioned as the substituents other than these can be suitably adopted.

As the aromatic ring having 5 to 60 ring members in R², an aromatic ring obtained by extending the aromatic ring having 5 to 40 ring members in Ar¹ of the formula (1) to an aromatic ring having 60 ring members can be suitably adopted. Examples of the aromatic ring having more than 40 ring members include a condensed ring structure such as a hexabenzocoronene ring, and an assembled ring structure (polycyclic structure in which rings are bonded with single bonds) such as a hexaphenylbenzene ring. Examples of the monovalent group containing an aromatic ring having 5 to 60 ring members, represented by R², include a group in which one hydrogen atom is removed from the aromatic ring having 5 to 60 ring members.

As the aromatic heterocycle having 5 to 20 ring members in R², a heteroaromatic ring having 5 to 20 ring members among the aromatic rings having 5 to 40 ring members in Ar¹ of the formula (1) can be suitably adopted. Examples of the monovalent group containing an aromatic heterocycle having 5 to 20 ring members, represented by R², include a group in which one hydrogen atom is removed from the aromatic heterocycle having 5 to 20 ring members.

Examples of the divalent linking group represented by L¹ include a divalent linear or branched hydrocarbon group having 1 to 10 carbon atoms, a divalent alicyclic hydrocarbon group having 4 to 12 carbon atoms, a divalent aromatic hydrocarbon group having 6 to 12 carbon atoms, one type of group selected from —CO—, —O—, —NH—, —S— or a cyclic acetal structure, and a group formed by combining two or more of these groups.

Examples of the divalent linear or branched hydrocarbon group having 1 to 10 carbon atoms include a methanediyl group, an ethanediyl group, a propanediyl group, a butanediyl group, a hexanediyl group, and an octanediyl group. In particular, an alkanediyl group having 1 to 8 carbon atoms is preferable.

Examples of the divalent alicyclic hydrocarbon group having 4 to 12 carbon atoms include monocyclic cycloalkanediyl groups such as a cyclopentanediyl group and a cyclohexanediyl group, and polycyclic cycloalkanediyl groups such as a norbornanediyl group and an adamantanediyl group. Among these, cycloalkanediyl groups having 5 to 12 carbon atoms are preferable.

Examples of the divalent aromatic hydrocarbon group having 6 to 12 carbon atoms include a benzenediyl group and a naphthalenediyl group.

L¹ is preferably a single bond.

As the aromatic ring having 5 to 60 ring members in Ar^{α}, an aromatic ring having 5 to 60 ring members in R² can be suitably adopted. The aromatic ring is preferably a fluorene ring. Examples of the divalent group containing an aromatic ring having 5 to 60 ring members, represented by Ard, include a group in which two hydrogen atoms are removed from one carbon atom in the aromatic ring having 5 to 60 ring members.

It is only required that at least one selected from the group consisting of Ar², Ar³, R², Ar^{α}, and L¹ has a nitro group, but it is preferable that R² has a nitro group. Among these, it is preferable that some or all of the hydrogen atoms on the aromatic ring having 5 to 60 ring members in R² are substituted with nitro groups. The number of nitro groups on the aromatic ring is preferably an integer from 1 to 4, more preferably an integer from 1 to 3, still more preferably 1 or 2 from the viewpoint of the proximity attracting action and solubility of the polymer [A1], and the like.

Examples of the repeating unit represented by the formula (5) include repeating units represented by formulas (5-1) to (5-4).

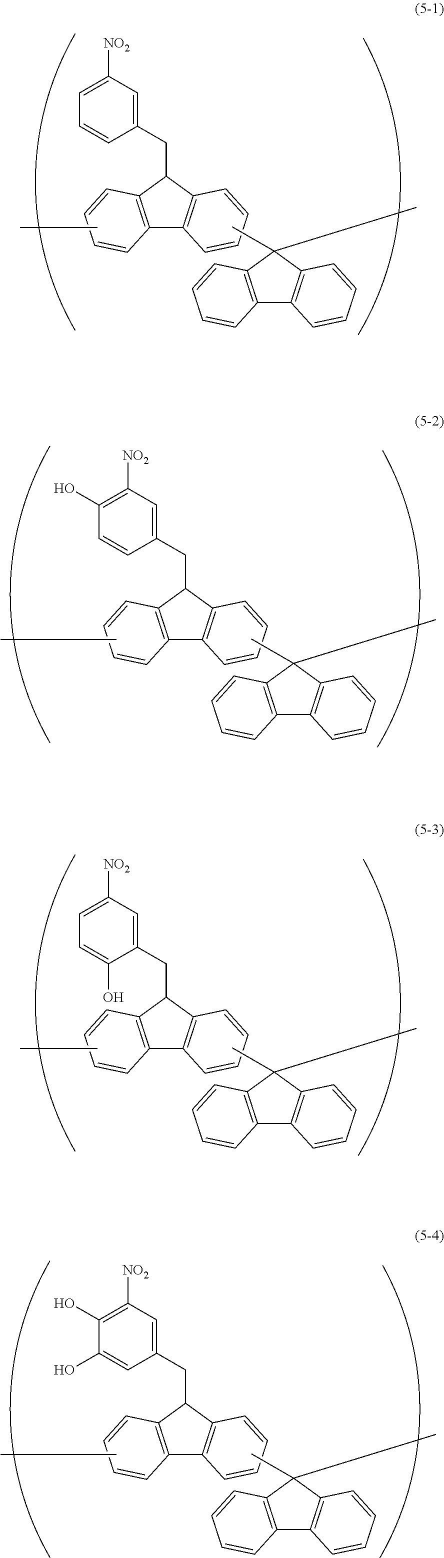

The polymer [A] may further have a repeating unit represented by formula (3) (however, excluding the repeating unit corresponding to the formula (1)).

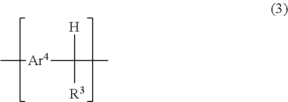

(In the formula (3), Ar⁴ is a divalent group having an aromatic ring having 5 to 40 ring atoms, and R³ is a hydrogen atom or a monovalent organic group having 1 to 60 carbon atoms).

As the aromatic ring having 5 to 40 ring atoms in Ar⁴, the aromatic ring having 5 to 40 ring atoms in Ar¹ of the formula (1) and the like can be suitably adopted.

Suitable examples of the divalent group having an aromatic ring having 5 to 40 ring atoms, represented by Ar⁴, include a group in which two hydrogen atoms are removed from the aromatic ring having 5 to 40 ring atoms in Ar⁴.

As the monovalent organic group having 1 to 60 carbon atoms, represented by R³, a group obtained by extending the group exemplified a group constituting the monovalent organic group having 1 to 40 carbon atoms, represented by R¹ in the formula (1), to a group having 60 carbon atoms can be suitably adopted.

Examples of the repeating unit represented by the formula (3) include repeating units represented by formulas (3-1) to (3-8).

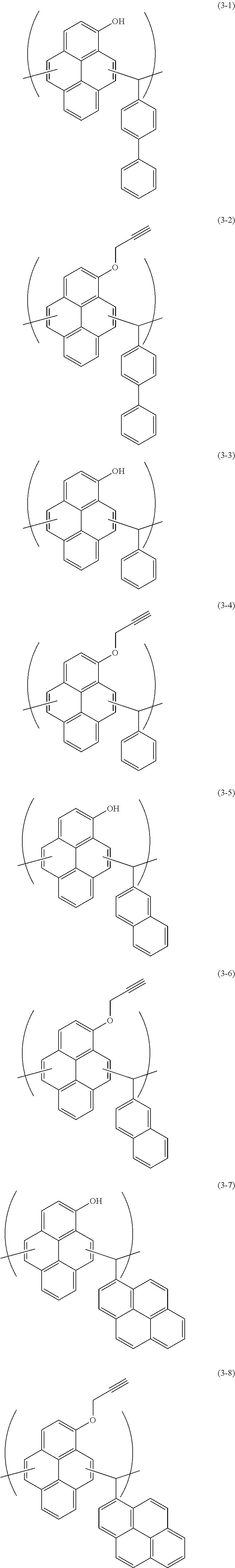

The lower limit of the weight average molecular weight of the polymer [A1] is preferably 500, more preferably 1,000, still more preferably 1,500. The upper limit of the molecular weight is preferably 10,000, more preferably 7,000, still more preferably 5,000. The weight average molecular weight is measured as described in Examples.

### (Method for Manufacturing Polymer [A1])

The polymer [A1] can typically be manufactured by acid addition condensation of an aromatic ring compound as a precursor having a phenolic hydroxyl group that affords Ar¹ in the formula (1) and an aldehyde derivative as a precursor to afford R⁰ and R¹ in the formula (1). Furthermore, it is possible to manufacture the polymer [A1] having a group (xx) introduced as a substituent by a nucleophilic substitution reaction of a phenolic hydroxyl group with a halogenated hydrocarbon corresponding to the group (α) represented by the formula (2-1) or (2-2). An acid catalyst is not particularly limited, and publicly known inorganic acids and organic acids can be used. After the reaction, the polymer [A1] can be obtained through separation, purification, drying, and the like. Other structures can also be produced by appropriately changing the structures of the aromatic ring compound, aldehyde derivative, and substituents, etc., used as precursors. As the reaction solvent, the solvent [B] described later can be suitably employed.

### (Other Polymers [A1])

As the polymers [A1], in addition to the novolac-based polymer described above, a resol-based polymer, a polyarylene-based polymer, a triazine-based polymer, a calixarene-based polymer, and the like can be used. It is preferred that some or all of the hydrogen atoms on the aromatic rings of these polymers are substituted with nitro groups. These polymers can be produced by a known method.

### (Resol-Based Polymer)

The resol-based polymer is a polymer obtained by reacting a phenolic compound with an aldehyde using an alkaline catalyst.

Examples of the phenolic compound include:
phenols such as phenol, cresol, xylenol, resorcinol, and bisphenol A;
naphthols such as 1-naphthol, 2-naphthol, 1,5-dihydroxynaphthalene, 2,7-dihydroxynaphthalene, and 9,9-bis(6-hydroxynaphthyl) fluorene;
anthrols such as 9-anthrol; and
hydroxypyrenes such as 1-hydroxypyrene and 2-hydroxypyrene.

Examples of the aldehyde include:
aldehydes such as formaldehyde, acetaldehyde, benzaldehyde, 1-pyrenecarboxaldehyde; and
aldehyde sources such as paraformaldehyde, trioxane, and paraldehyde.

### (Polyarylene-Based Polymer)

The polyarylene-based polymer is a polymer having a structural unit derived from a compound containing an arylene skeleton. Examples of the arylene skeleton include a phenylene skeleton, a naphthylene skeleton, and a biphenylene skeleton.

Examples of the polyarylene-based polymer include a polyarylene ether, a polyarylene sulfide, a polyarylene ether sulfone, a polyarylene ether ketone, and a polymer having a structural unit containing a biphenylene skeleton and a structural unit derived from a compound containing an acenaphthylene skeleton.

### (Triazine-Based Polymer)

The triazine-based polymer is a polymer having a structural unit derived from a compound having a triazine skeleton. Examples of the compound having a triazine skeleton include a melamine compound and a cyanuric acid compound.

### (Calixarene-Based Polymer)

A calixarene-based polymer is a cyclic oligomer in which a plurality of aromatic rings to which a hydroxyl group is bonded are bonded via hydrocarbon groups in a cyclic form or a compound in which some or all of the hydrogen atoms in the hydroxy groups, aromatic rings, and hydrocarbon groups are substituted.

In a case where the polymer [A1] is a resol-based polymer, a polyarylene-based polymer, or a triazine-based polymer, the lower limit of the weight average molecular weight of the polymer [A1] is preferably 500, more preferably 1,000, still more preferably 1,500. The upper limit of the molecular weight is preferably 10000, more preferably 8000, still more preferably 6000. The weight average molecular weight is measured as described in Examples.

In a case where the polymer [A1] is a calixarene-based polymer, the lower limit of the molecular weight of the polymer [A1] is preferably 500, more preferably 600, still more preferably 800. The upper limit of the molecular weight is preferably 5,000, more preferably 3,000, still more preferably 1,500.

### (Aromatic Ring-Containing Compound [A2])

The aromatic ring-containing compound [A2] is not particularly limited as long as it is a compound having a nitro group and a molecular weight of 600 or more and 3000 or less (however, excluding compounds corresponding to the polymer [A1]). The lower limit of the molecular weight of the aromatic ring-containing compound [A2] is preferably 750, more preferably 850, still more preferably 950. The upper limit of the molecular weight is preferably 3000, more preferably 2500, still more preferably 2000.

The aromatic ring-containing compound [A2] is preferably a compound represented by formula (3).

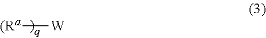

(In the formula (3),
W is a q-valent group containing a substituted or unsubstituted aromatic ring having 5 to 60 ring members,
R^{a} is a monovalent group containing an aromatic ring having 5 to 40 ring members,
q is an integer from 1 to 10, when q is 2 or more, a plurality of R^{a}s are the same as or different from each other, and
at least one selected from the group consisting of W and one R^{a} or a plurality of R^{a}s has a nitro group).

In the formula (3), it is preferred that one R^{a} or a plurality of R^{a}s have a nitro group, it is more preferred that at least one of a plurality of R^{a}s has a nitro group, and it is still more preferred that all of a plurality of R^{a}s have a nitro group.

As the aromatic ring having 5 to 60 ring members in W, an aromatic ring obtained by extending the aromatic ring having 5 to 40 ring members in Ar¹ of the formula (1) to an aromatic ring having 60 ring members can be suitably adopted. Examples of the q-valent group represented by W and containing a substituted or unsubstituted aromatic ring having 5 to 60 ring members include a group in which q hydrogen atoms are removed from the aromatic ring having 5 to 60 ring members. As the substituent in the case where W has a substituent other than a nitro group, a hydroxy group, the group (α), and the substituents mentioned as the substituents other than these can be suitably adopted.

The aromatic ring of W is preferably at least one aromatic hydrocarbon ring selected from the group consisting of a benzene ring, a naphthalene ring, an anthracene ring, a phenalene ring, a phenanthrene ring, a pyrene ring, a fluorene ring, a perylene ring, and a coronene ring.

In a case where W has a nitro group, it is preferred that at least one hydrogen atom of the aromatic ring in W is substituted with a nitro group.

As the aromatic ring having 5 to 40 ring members in R^{a}, an aromatic ring having 5 to 40 ring members in Ar¹ of the formula (1) can be suitably adopted. Examples of the monovalent group containing an aromatic ring having 5 to 40 ring members, represented by R^{a}, include a group in which one hydrogen atom is removed from the aromatic ring having 5 to 40 ring members. The aromatic ring of R^{a} is preferably at least one aromatic hydrocarbon ring selected from the group consisting of a benzene ring, a naphthalene ring, an anthracene ring, a phenalene ring, a phenanthrene ring, a pyrene ring, a fluorene ring, a perylene ring, and a coronene ring. As the substituent in the case where R^{a} has a substituent, a hydroxy group, the group (α), and the substituents mentioned as the substituents other than these can be suitably adopted.

R^{a} is preferably a group represented by formula (3-1) or (3-2).

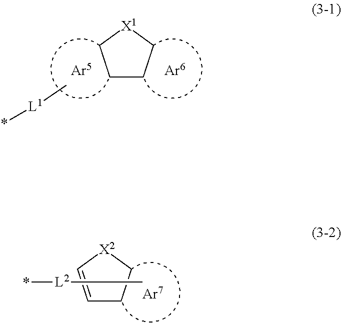

(In the formulas (3-1) and (3-2), X¹ and X² are each independently a group represented by formula (i), (ii), (iii) or (iv), Ar⁵, Ar⁶ and Ar⁷ are each independently a substituted or unsubstituted aromatic ring having 6 to 20 ring members that forms a condensed ring structure together with two adjacent carbon atoms in the formulas (3-1) and (3-2), L¹ and L² are each independently a single bond or a divalent organic group having an aromatic ring, and * is a bond with a carbon atom in W of the formula (3)).

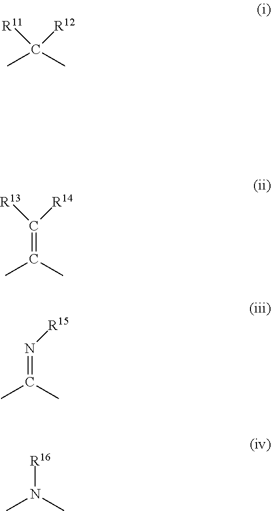

(In the formula (i), R¹¹ and R¹² are each independently a hydrogen atom or a monovalent organic group having 1 to 20 carbon atoms, and at least one of R¹¹ or R¹² has a nitro group,
in the formula (ii), R¹³ is a hydrogen atom or a monovalent organic group having 1 to 20 carbon atoms, R¹⁴ is a monovalent organic group having 1 to 20 carbon atoms, and at least one of R¹³ or R¹⁴ has a nitro group,
in the formula (iii), R¹⁵ is a monovalent organic group having 1 to 20 carbon atoms and having a nitro group, and
in the formula (iv), R¹⁶ is a monovalent organic group having 1 to 20 carbon atoms and having a hydrogen atom or a nitro group).

In the formulas (3-1) and (3-2), Ar⁵, Ar⁶ and Ar⁷ (hereinafter, sometimes referred to as “Ar⁵ to Ar⁷”) are each independently a substituted or unsubstituted aromatic ring having 6 to 20 ring members that forms a condensed ring structure together with two adjacent carbon atoms in the formulas (3-1) and (3-2). As the aromatic ring having 6 to 20 ring members in Ar⁵ to Ar⁷, aromatic rings corresponding to 6 to 20 ring members among the aromatic rings having 5 to 40 ring members in Ar¹ of the formula (1) can be suitably adopted.

As the substituent in the case where Ar⁵ to Ar⁷ have a substituent other than a nitro group, a hydroxy group, the group (α), and the substituents mentioned as the substituents other than these can be suitably adopted.

Examples of the monovalent organic group having 1 to 20 carbon atoms represented by R¹¹, R¹², R¹³, R¹⁴, R¹⁵, and R¹⁶ (hereinafter, sometimes referred to as “R¹¹ to R¹⁶”) in the formulas (i), (ii), (iii), and (iv) include a group corresponding to 1 to 20 carbon atoms among the monovalent organic groups having 1 to 40 carbon atoms, represented by R⁰ and R¹ of the formula (1).

It is preferred that at least one of R¹¹ or R¹² in the formula (i), at least one of R¹³ or R¹⁴ in the formula (ii), R¹⁵ in the formula (iii), and R¹⁶ in the formula (iv) each have an aromatic ring having 5 to 40 ring members. As the aromatic ring having 5 to 40 ring members, the aromatic rings having 5 to 40 ring members in Ar¹ of the formula (1) can be suitably adopted. In this case, it is preferred that at least one hydrogen atom of the aromatic ring is substituted with a nitro group. The number of nitro groups on the aromatic ring is preferably an integer from 1 to 4, more preferably an integer from 1 to 3, still more preferably 1 or 2.

Suitable examples of the divalent organic group having an aromatic ring in L¹ and L² in the formulas (3-1) and (3-2) include a substituted or unsubstituted group in which two hydrogen atoms are removed from an aromatic ring having 5 to 40 ring members in Ar¹ of the formula (1) (hereinafter also referred to as “group (β)”). The divalent organic group having an aromatic ring represented by L¹ and L² may be a group formed by combining the group (β) with a group obtained by removing one hydrogen atom from a monovalent organic group having 1 to 20 carbon atoms, represented by R¹¹ to R¹⁶. As the divalent organic group having an aromatic ring, represented by L¹ and L², a substituted or unsubstituted arenediyl group having 6 to 12 ring members, a substituted or unsubstituted alkenediyl group having 2 to 10 carbon atoms, an alkynediyl group having 2 to 10 carbon atoms, or a combination thereof are preferred, a benzenediyl group, a naphthalenediyl group, an ethylenediyl group, an ethynediyl group, or a combination thereof is more preferred, and a benzenediyl group or a combination of a benzenediyl group with an ethynediyl group is still more preferred.

In the formulas (3-1) and (3-2), L¹ and L² are preferably single bonds.

Examples of the aromatic ring-containing compound [A2] include compounds represented by formulas (3-1) to (3-12). In the formulas, the number attached to the structure showing Ar indicates the molar ratio in the aromatic ring-containing compound [A2], and * represents a bond to the methylidene carbon.

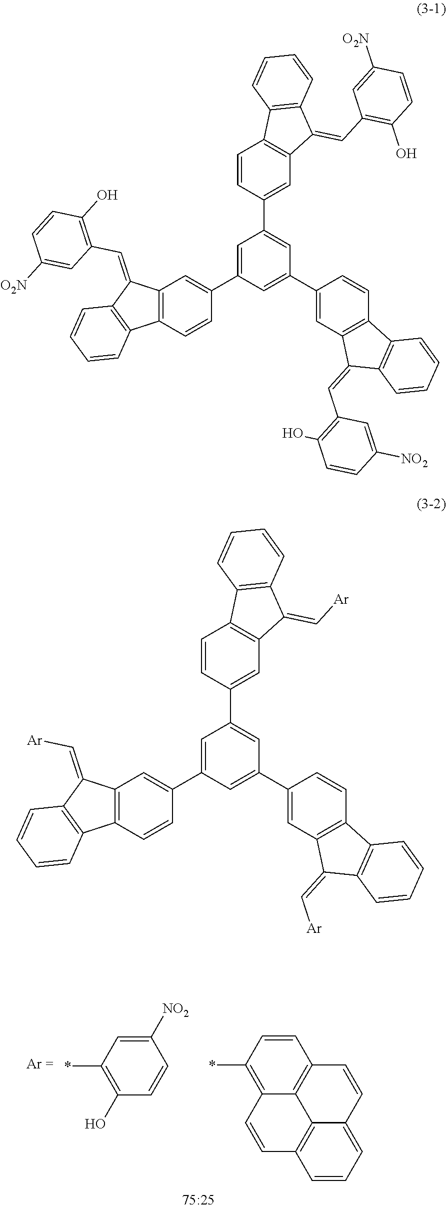

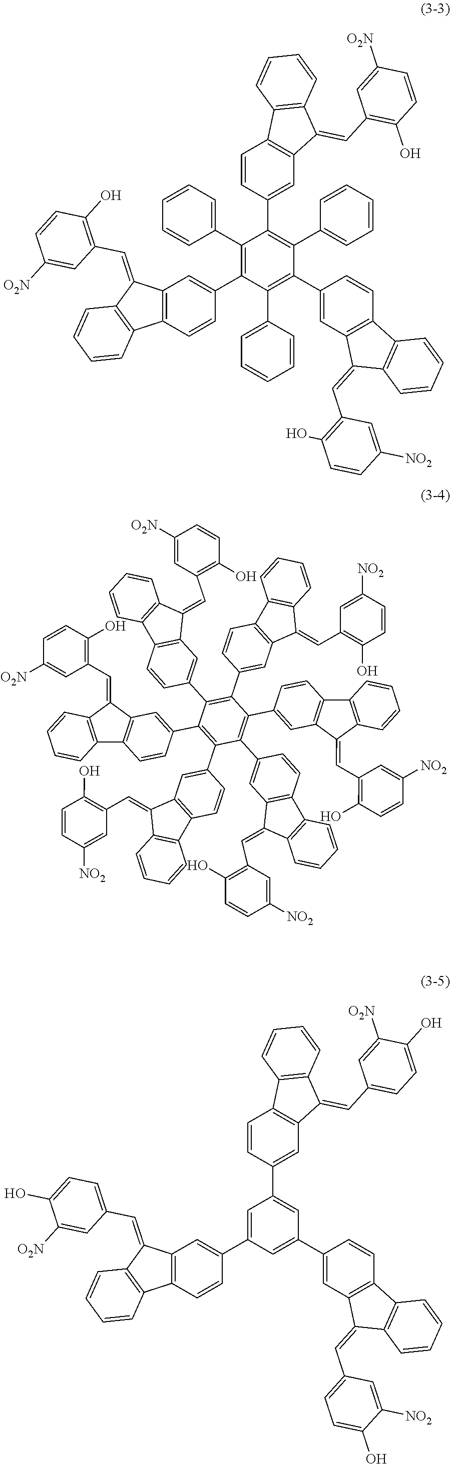

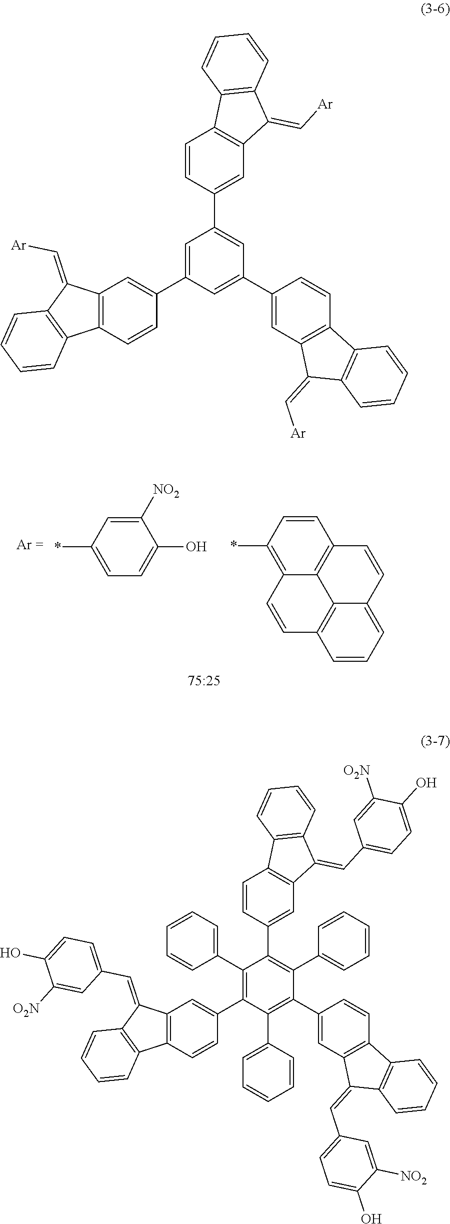

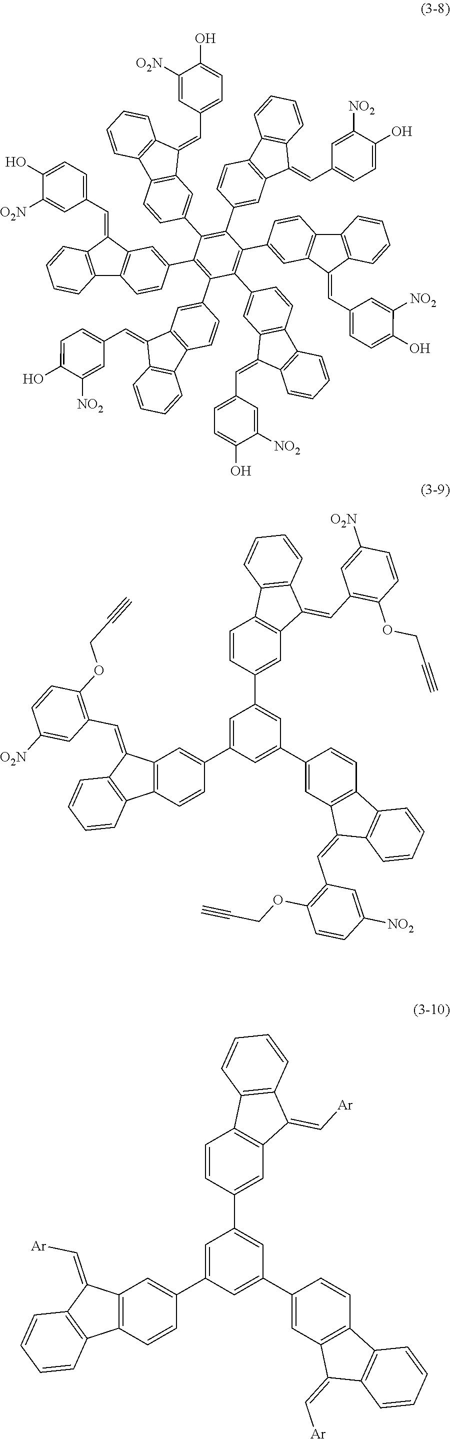

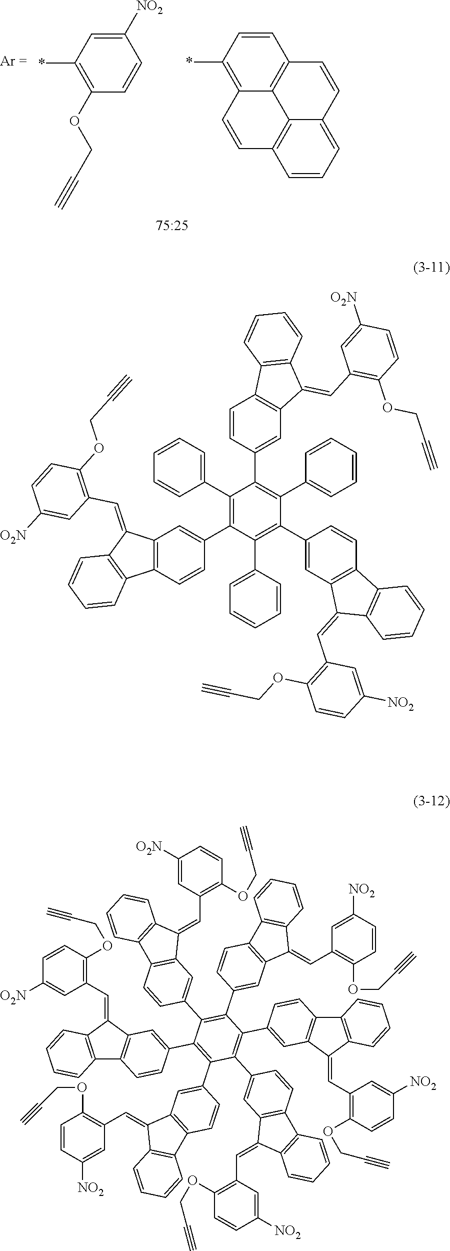

As the method for synthesizing the aromatic ring-containing compound [A2], typically, the aromatic ring-containing compound [A2] can be synthesized by preparing, for example, a ketone or alkyne-substituted fluorene as a starting material and conducting the cyclization reaction of the ketone moiety or alkyne moiety in the presence of a catalyst and the like. Other structures can also be synthesized by appropriately selecting the starting materials, the structure of the ketone body, and the like.

The content ratio of the compound [A] to the components other than the solvent in the composition is 10% by mass or more. The lower limit of the content ratio is preferably 30% by mass, more preferably 50% by mass, still more preferably 70% by mass, particularly preferably 908 by mass. The upper limit of the content ratio is preferably 100% by mass (that is, the composition contains only the compound [A] other than the solvent). In a case where the composition contains an optional component, the upper limit of the content ratio is preferably 99% by mass, more preferably 98% by mass.

The lower limit of the content ratio of the compound [A] in the composition is preferably 0.1% by mass, more preferably 0.5% by mass, still more preferably 18 by mass, particularly preferably 5% by mass in the total mass of the compound [A] and the solvent [B]. The upper limit of the content ratio is preferably 30% by mass, more preferably 25% by mass, still more preferably 20% by mass, particularly preferably 15% by mass in the total mass of the compound [A] and the solvent [B].

### <Solvent [B]>

The solvent [B] is not particularly limited as long as it can dissolve or disperse the compound [A] and optional components contained as necessary.

Examples of the solvent [B] include a hydrocarbon-based solvent, an ester-based solvent, an alcohol-based solvent, a ketone-based solvent, an ether-based solvent, and a nitrogen-containing solvent. The solvent [B] may be used singly or two or more kinds thereof may be used in combination.

Examples of the hydrocarbon-based solvent include aliphatic hydrocarbon-based solvents such as n-pentane, n-hexane, and cyclohexane, and aromatic hydrocarbon-based solvents such as benzene, toluene, and xylene.

Examples of the ester-based solvent include carbonate-based solvents such as diethyl carbonate, acetic acid monoacetate ester-based solvents such as methyl acetate and ethyl acetate, lactone-based solvents such as γ-butyrolactone, polyhydric alcohol partial ether carboxylate-based solvents such as diethylene glycol monomethyl ether acetate and propylene glycol monomethyl ether acetate, and lactate ester-based solvents such as methyl lactate and ethyl lactate.

Examples of the alcohol-based solvent include monoalcohol-based solvents such as methanol, ethanol, and n-propanol, and polyhydric alcohol-based solvents such as ethylene glycol and 1,2-propylene glycol.

Examples of the ketone-based solvent include chain ketone-based solvents such as methyl ethyl ketone and methyl isobutyl ketone, and cyclic ketone-based solvents such as cyclohexanone.

Examples of the ether-based solvent include chain ether-based solvents such as n-butyl ether, cyclic ether-based solvents such as tetrahydrofuran, polyhydric alcohol ether-based solvents such as propylene glycol dimethyl ether, and polyhydric alcohol partial ether-based solvents such as diethylene glycol monomethyl ether.

Examples of the nitrogen-containing solvent include chain nitrogen-containing solvents such as N,N-dimethylacetamide, and cyclic nitrogen-containing solvents such as N-methylpyrrolidone.

As the solvent [B], an ester-based solvent or a ketone-based solvent is preferable, a polyhydric alcohol partial ether carboxylate-based solvent or a cyclic ketone-based solvent is more preferable, and propylene glycol monomethyl ether acetate or cyclohexanone is still more preferable.

The lower limit of the content ratio of the solvent [B] in the composition is preferably 50% by mass, more preferably 60% by mass, and still more preferably 70% by mass. The upper limit of the content ratio is preferably 99.9% by mass, more preferably 99% by mass, and still more preferably 95% by mass.

### [Optional Component]

The composition may include an optional component as long as the effect of the composition is not impaired. Examples of the optional component include a compound obtained by removing a nitro group from the compound [A], an acid generator, a crosslinking agent, and a surfactant. The optional component may be used singly or two or more kinds thereof may be used in combination. The content ratio of the optional component in the composition can be appropriately determined according to the type and the like of the optional component.

### [Method for Preparing Composition]

The composition for forming a resist underlayer film can be prepared by mixing the compound [A], the solvent [B] and, as necessary, an optional component in a prescribed ratio and preferably filtering the resulting mixture through a membrane filter having a pore size of 0.5 μm or less and the like.

### [Applying Step]

In this step, a composition for forming a resist underlayer film is applied directly or indirectly to a substrate. In this step, the above-mentioned composition is used as a composition for forming a resist underlayer film.

The method of the application of the composition for forming a resist underlayer film is not particularly limited, and the application can be performed by an appropriate method such as spin coating, cast coating, or roll coating. As a result, a coating film is formed, and volatilization of the solvent [B] or the like occurs, so that a resist underlayer film is formed.

Examples of the substrate include metallic or semimetallic substrates such as a silicon substrate, an aluminum substrate, a nickel substrate, a chromium substrate, a molybdenum substrate, a tungsten substrate, a copper substrate, a tantalum substrate, and a titanium substrate. Among them, a silicon substrate is preferred. The substrate may be a substrate having a silicon nitride film, an alumina film, a silicon dioxide film, a tantalum nitride film, or a titanium nitride film formed thereon.

Examples of the case where the composition for forming a resist underlayer film is applied indirectly to the substrate include a case where the composition for forming a resist underlayer film is applied to a silicon-containing film described later formed on the substrate.

Next, the coating film formed by the application may be heated. The formation of the resist underlayer film is promoted by heating the coating film. More specifically, volatilization or the like of the solvent [B] is promoted by heating the coating film.

The heating of the coating film may be performed either in the air atmosphere or in a nitrogen atmosphere. The lower limit of the heating temperature is preferably 300° C., more preferably 320° C., and still more preferably 340° C. The upper limit of the heating temperature is preferably 600° C., and more preferably 500° C. The lower limit of the heating time is preferably 15 seconds, and more preferably 30 seconds. The upper limit of the time is preferably 1, 200 seconds, and more preferably 600 seconds.

After the applying step, the resist underlayer film may be subjected to exposure. After the applying step, the resist underlayer film may be exposed to plasma. After the applying step, the resist underlayer film may be ion-implanted. When the resist underlayer film is exposed, the etching resistance of the resist underlayer film is improved. When the resist underlayer film is exposed to plasma, the etching resistance of the resist underlayer film is improved. When the resist underlayer film is subjected to ion implantation, the etching resistance of the resist underlayer film is improved.

The radiation to be used for exposure of the resist underlayer film is appropriately selected from among electromagnetic waves such as visible rays, ultraviolet rays, far ultraviolet rays, X-rays, and γ-rays and corpuscular rays such as electron beam, molecular beams, and ion beams.

Examples of the method for exposing the resist underlayer film to plasma include a direct method in which a substrate is placed in each gas atmosphere and plasma discharge is performed. As plasma exposure conditions, usually, the gas flow rate is 50 cc/min or more and 100 cc/min or less, and the supply power is 100 W or more and 1, 500 W or less.

The lower limit of the time of the exposure to plasma is preferably 10 seconds, more preferably 30 seconds, and still more preferably 1 minute. The upper limit of the time is preferably 10 minutes, more preferably 5 minutes, and still more preferably 2 minutes.

The plasma is generated, for example, under an atmosphere of a mixed gas of H₂ gas and Ar gas. In addition to the H₂ gas and the Ar gas, a carbon-containing gas such as a CF₄ gas or a CH₄ gas may be introduced. At least one among a CF₄ gas, an NF₃ gas, a CHF₃ gas, a CO₂ gas, a CH₂F₂ gas, a CH₄ gas, and a C₄F₈ gas may be introduced instead of one or both of the H₂ gas and the Ar gas.

In the ion implantation into the resist underlayer film, a dopant is implanted into the resist underlayer film. The dopant may be selected from the group consisting of boron, carbon, nitrogen, phosphorus, arsenic, aluminum, and tungsten. The implantation energy utilized to apply a voltage to the dopant may be from about 0.5 keV to 60 keV depending on the type of the dopant to be utilized and a desired depth of implantation.

The lower limit of the average thickness of the resist underlayer film to be formed is preferably 30 nm, more preferably 50 nm, and still more preferably 100 nm. The upper limit of the average thickness is preferably 3,000 nm, more preferably 2,000 nm, and still more preferably 500 nm. The average thickness is measured as described in Examples.

### [Silicon-Containing Film Forming Step]

In this step, a silicon-containing film is formed directly or indirectly on the resist underlayer film formed through the applying step. Examples of the case where the silicon-containing film is formed indirectly on the resist underlayer film include a case where a surface modification film of the resist underlayer film is formed on the resist underlayer film. The surface modification film of the resist underlayer film is, for example, a film having a contact angle with water different from that of the resist underlayer film.

The silicon-containing film can be formed by, for example, application, chemical vapor deposition (CVD), atomic layer deposition (ALD), or the like of a composition for forming a silicon-containing film. Examples of a method for forming a silicon-containing film by application of a composition for forming a silicon-containing film include a method in which a coating film formed by applying a composition for forming a silicon-containing film directly or indirectly to the resist underlayer film is cured by exposure and/or heating. As a commercially available product of the composition for forming a silicon-containing film, for example, “NFC SOG01”, “NFC SOG04”, or “NFC SOG080” (all manufactured by JSR Corporation) can be used. By chemical vapor deposition (CVD) or atomic layer deposition (ALD), a silicon oxide film, a silicon nitride film, a silicon oxynitride film, or an amorphous silicon film can be formed.

Examples of the radiation to be used for the exposure include electromagnetic waves such as visible rays, ultraviolet rays, far ultraviolet rays, X-rays, and γ-rays and corpuscular rays such as electron beam, molecular beams, and ion beams.

The lower limit of the temperature in heating the coating film is preferably 90° C., more preferably 150° C., still more preferably 180° C. The upper limit of the temperature is preferably 550° C., more preferably 450° C., and still more preferably 350° C. The heating may be carried out in one stage or in multiple stages.

The lower limit of the average thickness of the silicon-containing film is preferably 1 nm, more preferably 10 nm, and still more preferably 20 nm. The upper limit is preferably 20,000 nm, more preferably 1,000 nm, and still more preferably 100 nm. The average thickness of the silicon-containing film is a value measured using the spectroscopic ellipsometer in the same manner as for the average thickness of the resist underlayer film.

### [Resist Pattern Forming Step]

In this step, a resist pattern is formed directly or indirectly on the resist underlayer film. Examples of a method for performing this step include a method using a resist composition, a method using nanoimprinting, and a method using a self-assembly composition. Examples of the case of forming a resist pattern indirectly on the resist underlayer film include a case of forming a resist pattern on the silicon-containing film.

Examples of the resist composition include a positive or negative chemically amplified resist composition containing a radiation-sensitive acid generator, a positive resist composition containing an alkali-soluble resin and a quinonediazide-based photosensitizer, a negative resist composition containing an alkali-soluble resin and a crosslinking agent, and a metal-containing resist composition containing a metal such as tin, zirconium, or hafnium.

Examples of the method of applying the resist composition include a spin coating method. The temperature and time of the prebaking may be appropriately adjusted according to the type or the like of the resist composition to be used.

Then, the formed resist film is subjected to exposure by selective irradiation with radiation. Radiation to be used for the exposure can be appropriately selected according to the type or the like of the radiation-sensitive acid generator to be used in the resist composition, and examples thereof include electromagnetic rays such as visible rays, ultraviolet rays, far-ultraviolet, X-rays, and γ-rays and corpuscular rays such as electron beam, molecular beams, and ion beams. Among these, far-ultraviolet rays are preferable, and KrF excimer laser light (wavelength: 248 nm), ArF excimer laser light (wavelength: 193 nm), F₂ excimer laser light (wavelength: 157 nm), Kr₂ excimer laser light (wavelength: 147 nm), ArKr excimer laser light (wavelength: 134 nm) or extreme ultraviolet rays (wavelength: 13.5 nm, etc., also referred to as “EUV”) are more preferred, and ArF excimer laser light or EUV is even more preferred.

After the exposure, post-baking may be performed to improve resolution, pattern profile, developability, etc. The temperature and time of the post-baking may be appropriately determined according to the type or the like of the resist composition to be used.

Then, the exposed resist film is developed with a developer to form a resist pattern. This development may be either alkaline development or organic solvent development. Examples of the developer for alkaline development include basic aqueous solutions such as ammonia, triethanolamine, tetramethylammonium hydroxide (TMAH), and tetraethylammonium hydroxide. To these basic aqueous solutions, for example, a water-soluble organic solvent such as an alcohol, e.g., methanol or ethanol, or a surfactant may be added in an appropriate amount. Examples of the developer for organic solvent development include the various organic solvents recited as examples of the solvent [B] in the composition described above.

After the development with a developer, a prescribed resist pattern is formed through washing and drying.

### [Etching Step]

In this step, etching is performed using the resist pattern as a mask. The number of times of the etching may be once. Alternatively, etching may be performed a plurality of times, that is, etching may be sequentially performed using a pattern obtained by etching as a mask. From the viewpoint of obtaining a pattern having a favorable shape, etching is preferably performed a plurality of times. When performed a plurality of times, etching is performed to the silicon-containing film, the resist underlayer film, and the substrate sequentially in order. Examples of an etching method include dry etching and wet etching. Dry etching is preferable from the viewpoint of achieving a favorable shape of the pattern of the substrate. In the dry etching, for example, gas plasma such as oxygen plasma is used. As a result of the etching, a semiconductor substrate having a prescribed pattern is obtained.

The dry etching can be performed using, for example, a publicly known dry etching apparatus. The etching gas used for dry etching can be appropriately selected according to the elemental composition of the film to be etched, and for example, fluorine-based gases such as CHF₃, CF₄, C₂F₆, C₃F₈, and SF₆, chlorine-based gases such as Cl₂ and BCl₃, oxygen-based gases such as O₂, O₃, and H₂O, reducing gases such as H₂, NH₃, CO, CO₂, CH₄, C₂H₂, C₂H₄, C₂H₆, C₃H₄, C₃H₆, C₃H₈, HF, HI, HBr, HCl, NO, and BCl₃, and inert gases such as He, N₂ and Ar are used. These gases can also be mixed and used. When the substrate is etched using the pattern of the resist underlayer film as a mask, a fluorine-based gas is usually used.

### <<Composition>>

The composition comprises a polymer [A] and a solvent [B]. As the composition, a composition to be used in the above-described method for manufacturing a semiconductor substrate can be suitably employed.

### EXAMPLES

Hereinbelow, the present invention will specifically be described on the basis of examples, but is not limited to these examples.

### [Weight-Average Molecular Weight (Mw)]

The Mw of a polymer was measured by gel permeation chromatography (detector: differential refractometer) with monodisperse polystyrene standards using GPC columns (“G2000HXL”×2, “G3000HXL”×1 and “G4000HXL”×1) manufactured by Tosoh Corporation under the following analysis conditions: flow rate: 1.0 mL/min; elution solvent: tetrahydrofuran; column temperature: 40° C.

### [Average Thickness of Resist Underlayer Film]

The average thickness of a film was determined as a value attained by measuring the film thickness at arbitrary nine points at intervals of 5 cm including the center of the resist underlayer film formed on a silicon wafer using a spectroscopic ellipsometer (“M2000D” available from J. A. WOOLLAM Co.) and calculating the average value of the film thicknesses.

### <Synthesis of Compound [A]>

Polymers having a repeating unit, represented by formulas (A-1) to (A-9), (A-14) to (A-16), (a-4), (a-5), (x-1) and (x-2), respectively (hereinafter, each may also be referred to as “polymer (A-1)” or the like), and aromatic ring-containing compounds represented by formulas (A-10) to (A-13) and (a-1) to (a-3), respectively (hereinafter, also referred to as “aromatic ring-containing compound (A-10)” and the like) were synthesized by the following procedure. In the formulas, when a number is attached to a repeating unit, the number represents the content ratio (mol %) of the repeating unit.

### [Synthesis Example 1] (Synthesis of Polymer (A-1))

In a nitrogen atmosphere, 39.6 g of 1-hydroxypyrene, 27.5 g of 3-nitrobenzaldehyde, and 185.0 g of 1-butanol were added into a reaction vessel and dissolved by performing heating to 80° C. After a solution of 10.4 g of p-toluenesulfonic acid monohydrate in 1-butanol (15.0 g) was added to the reaction vessel, the mixture was heated to 115° C. and reacted for 15 hours. After completion of the reaction, the reaction solution was transferred to a separatory funnel, 200 g of methyl isobutyl ketone and 400 g of water were added thereto, and the organic phase was washed. After the aqueous phase was separated, the obtained organic phase was concentrated with an evaporator, and the residue was added dropwise to 500 g of methanol to obtain a precipitate. The precipitate was collected by suction filtration and washed several times with 100 g of methanol. Then, the washed product was dried at 60° C. for 12 hours using a vacuum dryer, affording a polymer (A-1) having a repeating unit represented by formula (A-1). The Mw of the polymer (A-1) was 3,000.

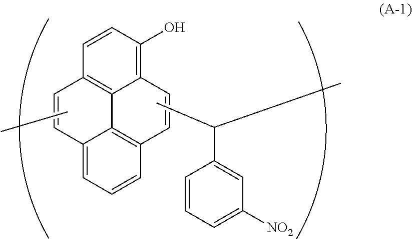

### [Synthesis Example 2] (Synthesis of Polymer (A-2))

A polymer (A-2) represented by the formula (A-2) was obtained in the same manner as in Synthesis Example 1 except that 27.5 g of 3-nitrobenzaldehyde was changed to 30.4 g of 2-hydroxy-5-nitrobenzaldehyde. The Mw of the polymer (A-2) was 3100.

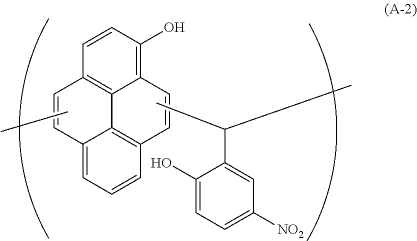

### [Synthesis Example 3] (Synthesis of Polymer (A-3))

A polymer (A-3) represented by the formula (A-3) was obtained in the same manner as in Synthesis Example 1 except that 27.5 g of 3-nitrobenzaldehyde was changed to 33.3 g of 3,4-dihydroxy-5-nitrobenzaldehyde. The Mw of the polymer (A-3) was 3300.

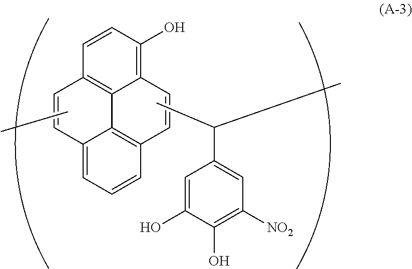

### [Synthesis Example 4] (Synthesis of Polymer (A-4))

A polymer (A-4) represented by the formula (A-4) was obtained in the same manner as in Synthesis Example 1 except that 27.5 g of 3-nitrobenzaldehyde was changed to 8.3 g of 3,4-dihydroxy-5-nitrobenzaldehyde and 25.0 g of 4-biphenylaldehyde. The Mw of the polymer (A-4) was 4000.

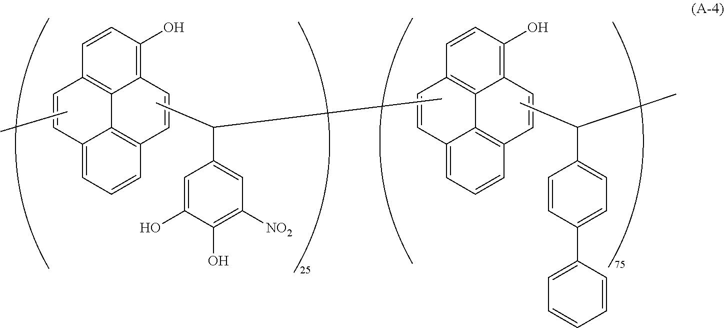

### [Synthesis Example 5] (Synthesis of Polymer (A-5))

A polymer (A-5) represented by the formula (A-5) was obtained in the same manner as in Synthesis Example 1 except that 39.6 g of 1-hydroxypyrene was changed to 17.1 g of phenol and 27.5 g of 3-nitrobenzaldehyde was changed to 30.4 g of 2-hydroxy-5-nitrobenzaldehyde. The Mw of the polymer (A-5) was 2200.

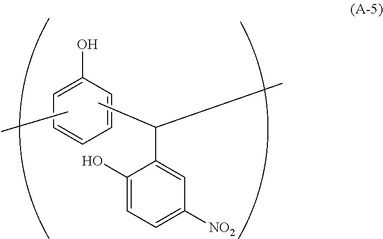

### [Synthesis Example 6] (Synthesis of Polymer (A-6))

A polymer (A-6) represented by the formula (A-6) was obtained in the same manner as in Synthesis Example 1 except that 39.6 g of 1-hydroxypyrene was changed to 26.2 g of 2-naphthol and 27.5 g of 3-nitrobenzaldehyde was changed to 30.4 g of 2-hydroxy-5-nitrobenzaldehyde. The Mw of the polymer (A-6) was 2500.

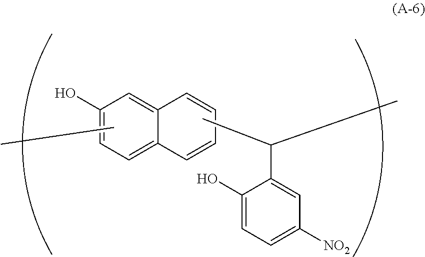

### [Synthesis Example 7] (Synthesis of Polymer (A-7))

A polymer (A-7) represented by the formula (A-7) was obtained in the same manner as in Synthesis Example 1 except that 39.6 g of 1-hydroxypyrene was changed to 29.1 g of 2,7-dihydroxynaphthalene and 27.5 g of 3-nitrobenzaldehyde was changed to 30.4 g of 2-hydroxy-5-nitrobenzaldehyde. The Mw of the polymer (A-7) was 2600.

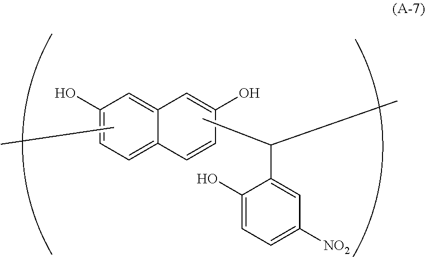

### [Synthesis Example 8] (Synthesis of Polymer (A-8))

In a nitrogen atmosphere, 15.0 g of the polymer (A-3), 15.7 g of propargyl bromide, 90.0 g of methyl isobutyl ketone, and 45.0 g of methanol were added into a reaction vessel and stirred. Then, 48.2 g of a 25% by mass aqueous tetramethylammonium hydroxide solution was added, and the reaction was conducted at 50° C. for 6 hours. The reaction solution was cooled to 30° C., and then 150.0 g of a 5% by mass aqueous oxalic acid solution was added. After the aqueous phase was removed, the obtained organic phase was concentrated with an evaporator, and the residue was added dropwise to 300 g of methanol to obtain a precipitate. The precipitate was collected by suction filtration and washed several times with 60 g of methanol. Then, the washed product was dried at 60° C. for 12 hours using a vacuum dryer, thereby obtaining a polymer (A-8) represented by formula (A-8). The Mw of the polymer (A-8) was 4200.

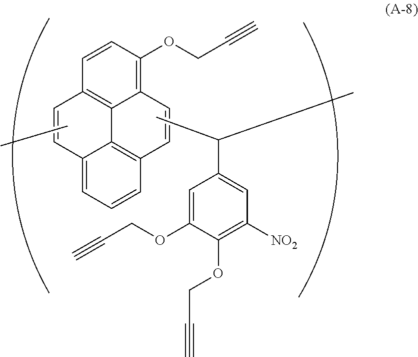

### [Synthesis Example 9] (Synthesis of Polymer (A-9))

A polymer (A-9) represented by formula (A-9) was obtained in the same manner as in Synthesis Example 8 except that 15.7 g of propargyl bromide was changed to 15.8 g of bromoacetonitrile. The Mw of the polymer (A-9) was 4300.

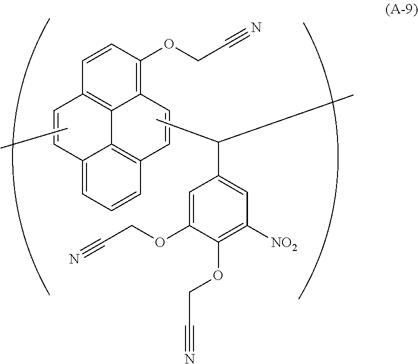

### [Synthesis Example 10] (Synthesis of Aromatic Ring-Containing Compound (a-1))

In a nitrogen atmosphere, 20.0 g of 2-acetylfluorene and 20.0 g of m-xylene were added into a reaction vessel, and dissolved at 110° C. Next, 3.1 g of dodecylbenzenesulfonic acid was added, and the mixture was heated to 140° C. and reacted for 16 hours. After completion of the reaction, 80 g of xylene was added to this reaction solution to dilute the solution, and then the diluted solution was cooled to 50° C. and charged into 500.0 g of methanol for reprecipitation. The obtained precipitate was washed with toluene, then the solid was collected on filter paper and dried, thereby obtaining an aromatic ring-containing compound (a-1) represented by formula (a-1).

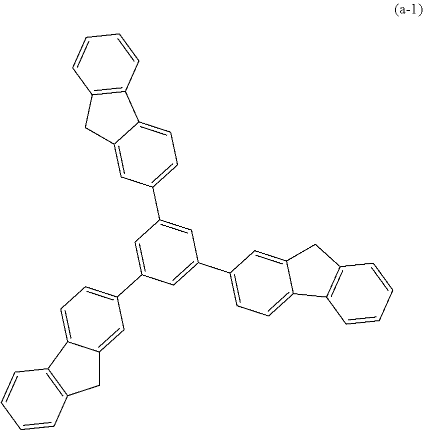 [SMILES: c1ccc2c(c1)Cc1cc(-c3cc(-c4ccc5c(c4)Cc4ccccc4-5)cc(-c4ccc5c(c4)Cc4ccccc4-5)c3)ccc1-2]

### [Synthesis Example 11] (Synthesis of Aromatic Ring-Containing Compound (A-10))

In a nitrogen atmosphere, 10.0 g of the compound (a-1), 9.7 g of 2-hydroxy-5-nitrobenzaldehyde, 21.1 g of a 25% by mass aqueous tetramethylammonium hydroxide solution, 0.6 g of tetra-n-butylammonium bromide, and 60.0 g of tetrahydrofuran were added into a reaction vessel, and reacted at 70° C. for 5 hours. The reaction solution was cooled to 30° C. and then charged into 200.0 g of methanol for reprecipitation. The precipitate was collected on filter paper and dried to obtain an aromatic ring-containing compound (A-10) represented by formula (A-10).

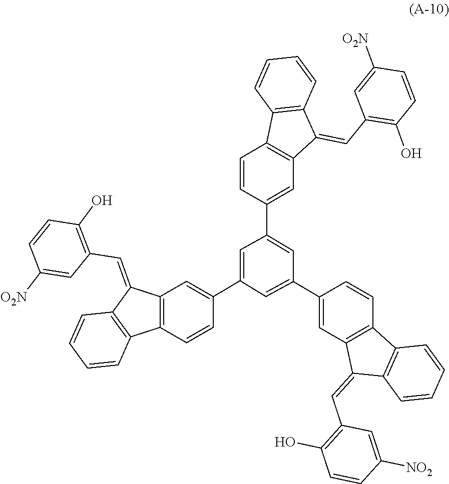 [SMILES: O=[N+]([O-])c1ccc(O)c(/C=C2\c3ccccc3-c3ccc(-c4cc(-c5ccc6c(c5)/C(=C/c5cc([N+](=O)[O-])ccc5O)c5ccccc5-6)cc(-c5ccc6c(c5)/C(=C/c5cc([N+](=O)[O-])ccc5O)c5ccccc5-6)c4)cc32)c1]

### [Synthesis Example 12] (Synthesis of Aromatic Ring-Containing Compound (A-11))

An aromatic ring-containing compound (A-11) represented by formula (A-11) was obtained in the same manner as in Synthesis Example 11 except that 9.7 g of 2-hydroxy-5-nitrobenzaldehyde was changed to 4.8 g of 2-hydroxy-5-nitrobenzaldehyde and 6.7 g of 1-pyrenecarboxaldehyde. In formula, the ratio of R¹¹ is a molar ratio, and * is a bond with the methylidene carbon.

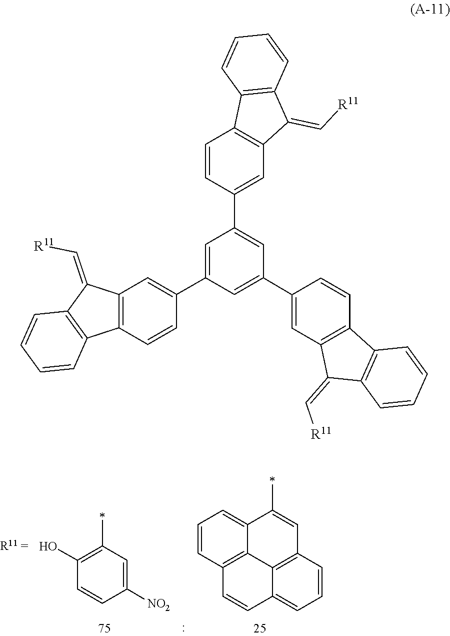

### [Synthesis Example 13] (Synthesis of Aromatic Ring-Containing Compound (a-2))

In a nitrogen atmosphere, 20.0 g of 2-phenylethynylfluorene and 200 g of 1,4-dioxane were added into a reaction vessel, and dissolved at 50° C. Then, 1.28 g of dicobalt octacarbonyl was added, and the mixture was heated to 110° C. and reacted for 12 hours. After completion of the reaction, the reaction solution was cooled to room temperature, and 600 g of methanol and 60.0 g of water were added to obtain a precipitate. The obtained precipitate was collected on filter paper and dried to obtain an aromatic ring-containing compound (a-2).

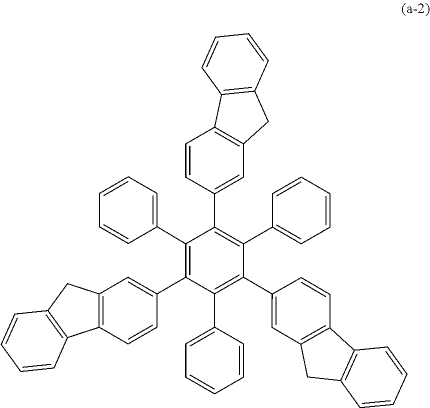 [SMILES: c1ccc(-c2c(-c3ccc4c(c3)Cc3ccccc3-4)c(-c3ccccc3)c(-c3ccc4c(c3)Cc3ccccc3-4)c(-c3ccccc3)c2-c2ccc3c(c2)Cc2ccccc2-3)cc1]

### [Synthesis Example 14] (Synthesis of Aromatic Ring-Containing Compound (A-12))

An aromatic ring-containing compound (A-12) represented by formula (A-12) was obtained in the same manner as in Synthesis Example 11, except that 10.0 g of the aromatic ring-containing compound (a-1) was changed to 14.0 g of the aromatic ring-containing compound (a-2).

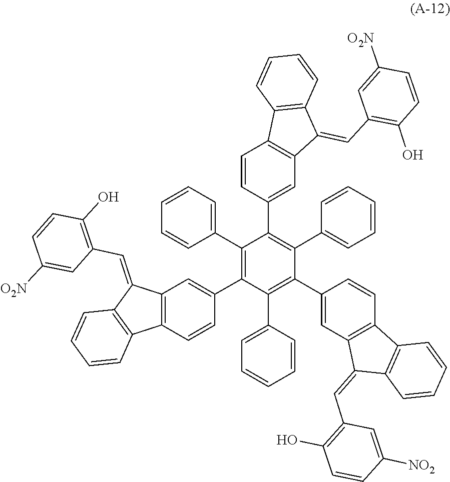 [SMILES: O=[N+]([O-])c1ccc(O)c(/C=C2\c3ccccc3-c3ccc(-c4c(-c5ccccc5)c(-c5ccc6c(c5)/C(=C/c5cc([N+](=O)[O-])ccc5O)c5ccccc5-6)c(-c5ccccc5)c(-c5ccc6c(c5)/C(=C/c5cc([N+](=O)[O-])ccc5O)c5ccccc5-6)c4-c4ccccc4)cc32)c1]

### [Synthesis Example 15] (Synthesis of Aromatic Ring-Containing Compound (a-3))

In a nitrogen atmosphere, 20.0 g of bis(2-fluorenyl)acetylene, 21.7 g of tetraphenylcyclopentadienone, and 125.0 g of sulfolane were added into a reaction vessel, stirred at 50° C., then heated to 210° C., and reacted for 8 hours. After completion of the reaction, the reaction solution was cooled to 30° C. and charged into a mixed solution of 125.0 g of methanol and 50.0 g of water for reprecipitation. The obtained precipitate was recrystallized from toluene, and the crystals were collected on filter paper and dried to obtain an aromatic ring-containing compound (a-3) represented by formula (a-3).

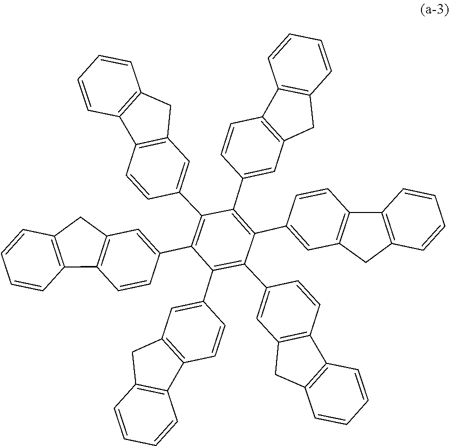 [SMILES: c1ccc2c(c1)Cc1cc(-c3c(-c4ccc5c(c4)Cc4ccccc4-5)c(-c4ccc5c(c4)Cc4ccccc4-5)c(-c4ccc5c(c4)Cc4ccccc4-5)c(-c4ccc5c(c4)Cc4ccccc4-5)c3-c3ccc4c(c3)Cc3ccccc3-4)ccc1-2]

### [Synthesis Example 16] (Synthesis of Aromatic Ring-Containing Compound (A-13))

An aromatic ring-containing compound (A-13) represented by formula (A-13) was obtained in the same manner as in Synthesis Example 11, except that 10.0 g of the aromatic ring-containing compound (a-1) was changed to 9.3 g of the aromatic ring-containing compound (a-3).

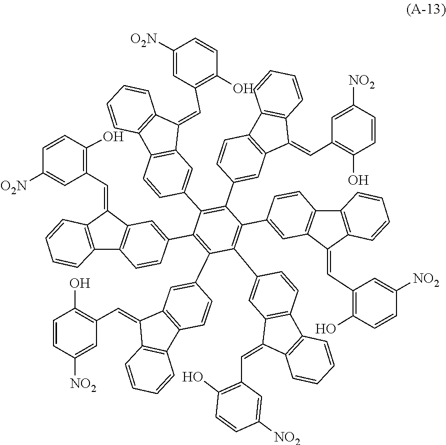 [SMILES: O=[N+]([O-])c1ccc(O)c(/C=C2\c3ccccc3-c3ccc(-c4c(-c5ccc6c(c5)/C(=C/c5cc([N+](=O)[O-])ccc5O)c5ccccc5-6)c(-c5ccc6c(c5)/C(=C/c5cc([N+](=O)[O-])ccc5O)c5ccccc5-6)c(-c5ccc6c(c5)/C(=C/c5cc([N+](=O)[O-])ccc5O)c5ccccc5-6)c(-c5ccc6c(c5)/C(=C/c5cc([N+](=O)[O-])ccc5O)c5ccccc5-6)c4-c4ccc5c(c4)/C(=C/c4cc([N+](=O)[O-])ccc4O)c4ccccc4-5)cc32)c1]

### [Synthesis Example 17] (Synthesis of Polymer (A-14))

In a nitrogen atmosphere, 10.0 g of resorcinol, 14.0 g of 4-nitrobenzaldehyde, and 120 g of ethanol were added into a reaction vessel and dissolved at room temperature. To the obtained solution, 27.0 g of concentrated hydrochloric acid was added dropwise over 1 hour, then the solution temperature was raised to 80° C., and aging was performed for 7 hours. After aging, cooling was performed until the solution temperature reached room temperature. Thereafter, the precipitated solid was collected by filtration, and the crystals were collected on filter paper and dried to obtain a polymer (A-14) represented by formula (A-14).

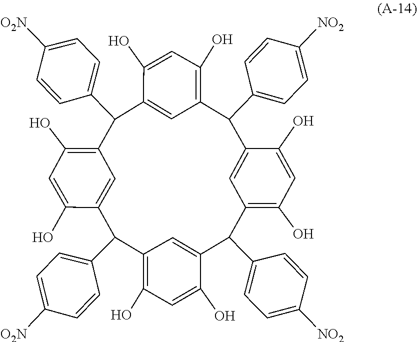 [SMILES: O=[N+]([O-])c1ccc(C2c3cc(c(O)cc3O)C(c3ccc([N+](=O)[O-])cc3)c3cc(c(O)cc3O)C(c3ccc([N+](=O)[O-])cc3)c3cc(c(O)cc3O)C(c3ccc([N+](=O)[O-])cc3)c3cc2c(O)cc3O)cc1]

### [Synthesis Example 18] (Synthesis of Compound (A-15))

A reaction vessel was charged with 12.5 g of 9,9-bis(3-nitro-4-hydroxyphenyl) fluorene, 37.5 g of propylene glycol monomethyl ether acetate, and 1.3 g of paraformaldehyde, 0.1 g of p-toluenesulfonic acid monohydrate was added, and the reaction was conducted at 100° C. for 16 hours. Thereafter, the polymerization reaction solution was charged into 100.0 g of a mixed solvent of methanol/water (70/30 (mass ratio)), and the precipitate was collected on filter paper and dried to obtain a polymer (A-15) represented by formula (A-15). The Mw of the obtained polymer (A-15) was 4,300.

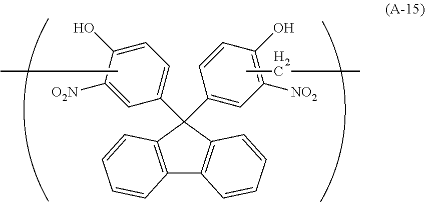

### [Synthesis Example 19] (Synthesis of Polymer (a-4))

A reaction vessel was charged with 10.0 g of fluorene, 7.6 g of 9-fluorenone, 18.1 g of trifluoromethanesulfonic acid, and 70.4 g of nitrobenzene, and the reaction was conducted at 120° C. for 15 hours. The reaction solution was cooled to 30° C. and then charged into 200.0 g of a mixed solvent of methanol/water (80/20 (mass ratio)), and the precipitate was collected on filter paper and dried to obtain a polymer (a-4) represented by formula (a-4). The Mw of the obtained polymer (a-4) was 4,200.

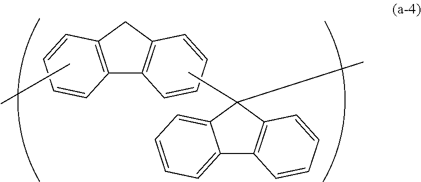

### [Synthesis Example 20] (Synthesis of Polymer (A-16))

A polymer (A-16) represented by formula (A-16) was obtained in the same manner as in Synthesis example 11, except that 10.0 g of aromatic ring-containing compound (a-1) was changed to 19.0 g of polymer (a-4), 9.7 g of 2-hydroxy-5-nitrobenzaldehyde was changed to 8.7 g of 3-nitrobenzaldehyde, and the amount of tetra-n-butylammonium bromide was changed from 0.6 g to 1.9 g. The Mw of the polymer (A-16) was 2500.

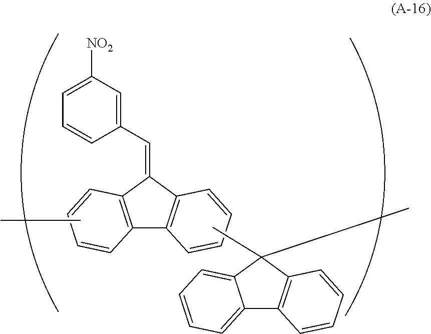

### [Comparative Synthesis Example 1] (Synthesis of Polymer (x-1))

In a nitrogen atmosphere, 250.0 g of m-cresol, 125.0 g of 37% by mass formalin, and 2 g of oxalic anhydride were added to a reaction vessel, and the mixture was reacted at 100° C. for 3 hours and at 180° C. for 1 hour, and then unreacted monomers were removed under reduced pressure, affording a polymer (x-1) having a repeating unit represented by formula (x-1). The Mw of the polymer (x-1) obtained was 11,000.

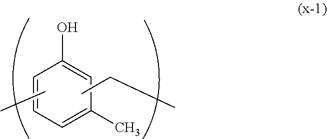

### [Comparative Synthesis Example 2] (Synthesis of Polymer (x-2))

In a nitrogen atmosphere, 39.8 g of 1-hydroxypyrene, 25.1 g of 3,4-dihydroxybenzaldehyde, and 120.0 g of 1-butanol were added into a reaction vessel and dissolved by performing heating to 80° C. After a solution of 10.4 g of p-toluenesulfonic acid monohydrate in 1-butanol (15.0 g) was added to the reaction vessel, the mixture was heated to 115° C. and reacted for 15 hours. After completion of the reaction, the reaction solution was transferred to a separatory funnel, 200 g of methyl isobutyl ketone and 400 g of water were added thereto, and the organic phase was washed. After separating the aqueous phase, the resulting organic phase was concentrated with an evaporator, and the residue was added dropwise to 500 g of methanol, affording a precipitate. The precipitate was collected by suction filtration and washed several times with 100 g of methanol. Then, the washed product was dried at 60° C. for 12 hours using a vacuum dryer, thereby obtaining a polymer (x-2) represented by formula (x-2). The Mw of the polymer (x-2) was 3,000.

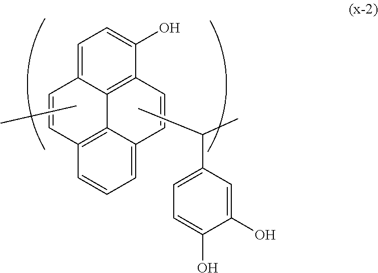

### <Preparation of Composition>

The compounds [A], the solvents [B], the acid generators [C], and the crosslinking agents [D] used for the preparation of compositions are shown below.

### [Compound [A]]

Examples: Compounds (A-1) to (A-16) synthesized above

[Compound [x]]

Comparative Examples: Compounds (x-1) and (x-2) synthesized above

### [Solvent [B]]

B-1: Propylene glycol monomethyl ether acetate
B-2: Cyclohexanone

### [Acid Generator [C]]

C-1: Bis(4-t-butylphenyl) iodonium nonafluoro-n-butanesulfonate (the compound represented by formula (C-1))

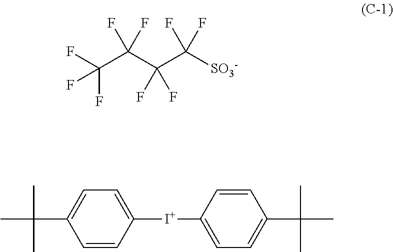

### [Crosslinking Agent [D]]

D-1: A compound represented by formula (D-1)

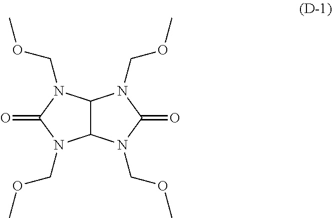 [SMILES: COCN1C(=O)N(COC)C2C1N(COC)C(=O)N2COC]

D-2: A compound represented by formula (D-2)

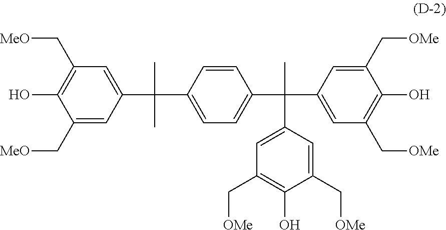 [SMILES: COCc1cc(C(C)(C)c2ccc(C(C)(c3cc(COC)c(O)c(COC)c3)c3cc(COC)c(O)c(COC)c3)cc2)cc(COC)c1O]

### Example 1

In 85 parts by mass of (B-2) as the solvent [B], 15 parts by mass of (A-1) as the compound [A] was dissolved. The resulting solution was filtered through a polytetrafluoroethylene (PTFE) membrane filter having a pore size of 0.45 μm to prepare composition (J-1).

### Examples 2 to 18 and Comparative Examples 1 and 2

Compositions (J-2) to (J-18), (CJ-1), and (CJ-2) were prepared in the same manner as in Example 1, except that the components of the types and contents shown in the following Table 1 were used. In Table 1, “-” in the columns of “compound (A)”, “compound (x)”, “acid generator (C)” and “crosslinking agent (D)” indicates that the corresponding component was not used.

TABLE 1

| | | | | | | | | Acid generator | | Crosslinking | |
|---|---|---|---|---|---|---|---|---|---|---|---|
| | | Compound [A] | | Compound [x] | | Solvent [B] | | [C] | | agent [D] | |
| | | | Content | | Content | | Content | | Content | | Content |
| | | | (parts | | (parts | | (parts | | (parts | | (parts |
| | Composition | Type | by mass) | Type | by mass) | Type | by mass) | Type | by mass) | Type | by mass) |
| Example 1 | J-1 | A-1 | 15 | — | — | B-2 | 85 | — | — | — | — |
| Example 2 | J-2 | A-2 | 15 | — | — | B-2 | 85 | — | — | — | — |
| Example 3 | J-3 | A-3 | 15 | — | — | B-2 | 85 | — | — | — | — |
| Example 4 | J-4 | A-4 | 15 | — | — | B-2 | 85 | — | — | — | — |
| Example 5 | J-5 | A-5 | 15 | — | — | B-2 | 85 | — | — | — | — |
| Example 6 | J-6 | A-6 | 15 | — | — | B-1 | 85 | — | — | — | — |
| Example 7 | J-7 | A-7 | 15 | — | — | B-1 | 85 | — | — | — | — |
| Example 8 | J-8 | A-8 | 15 | — | — | B-1 | 85 | — | — | — | — |
| Example 9 | J-9 | A-9 | 15 | — | — | B-2 | 85 | — | — | — | — |
| Example 10 | J-10 | A-10 | 15 | — | — | B-2 | 85 | — | — | — | — |
| Example 11 | J-11 | A-11 | 15 | — | — | B-2 | 85 | — | — | — | — |
| Example 12 | J-12 | A-12 | 15 | — | — | B-2 | 85 | — | — | — | — |
| Example 13 | J-13 | A-13 | 15 | — | — | B-2 | 85 | — | — | — | — |
| Example 14 | J-14 | A-14 | 15 | — | — | B-2 | 85 | — | — | — | — |
| Example 15 | J-15 | A-15 | 15 | — | — | B-1 | 85 | — | — | — | — |
| Example 16 | J-16 | A-16 | 15 | — | — | B-1 | 85 | — | — | — | — |
| Example 17 | J-17 | A-1 | 10 | x-1 | 2 | B-1 | 84.9 | C-1 | 0.1 | D-1 | 3 |
| Example 18 | J-18 | A-1 | 10 | x-1 | 2 | B-1 | 84.9 | C-1 | 0.1 | D-2 | 3 |
| Comparative | CJ-1 | — | — | x-1 | 15 | B-1 | 85 | — | — | — | — |
| Example 1 | | | | | | | | | | | |
| Comparative | CJ-2 | — | — | x-2 | 15 | B-1 | 85 | — | — | — | — |
| Example 2 | | | | | | | | | | | |

### <Evaluation>

Using the compositions obtained above, the solubility in polar solvents and bending resistance were evaluated by the following methods. The evaluation results are shown in the following Table 2.

### [Solubility in Polar Solvent]

To 5.0 g of the composition for forming a resist underlayer film prepared above, 5.0 g of 1-methoxy-2-propanol was added, and the mixture was stirred for 5 minutes and then allowed to stand for 10 minutes. The solubility was evaluated as “B” (poor) when insoluble matter was visually observed after standing, and as “A” (good) when insoluble matter was not observed.

### [Bending Resistance]

The composition prepared as described above was applied to a silicon substrate with a silicon dioxide film formed thereon having an average thickness of 500 nm, by a spin coating method using a spin coater (“CLEAN TRACK ACT 12” available from Tokyo Electron Limited). Next, the resultant was heated at 350° C. for 60 seconds in the air atmosphere, and then cooled at 23° C. for 60 seconds, thereby affording a substrate with film, the substrate having thereon a resist underlayer film having an average thickness of 200 nm. A composition for forming a silicon-containing film (“NFC SOG080” manufactured by JSR Corporation) was applied to the resulting substrate with film by a spin coating method, and then heated at 200° C. for 60 seconds in the air atmosphere, and further heated at 300° C. for 60 seconds, thereby forming a silicon-containing film having an average thickness of 50 nm. A resist composition for ArF (“AR1682J” manufactured by JSR Corporation) was applied to the silicon-containing film by a spin coating method, and heated (fired) at 130° C. for 60 seconds in the air atmosphere, thereby forming a resist film having an average thickness of 200 nm. The resist film was exposed with varying an exposure amount through a 1:1 line-and-space mask pattern with a target size of 100 nm using an ArF excimer laser exposure apparatus (lens numerical aperture: 0.78, exposure wavelength: 193 nm), and then heated (fired) at 130° C. for 60 seconds in the air atmosphere, developed at 25° C. for 1 minute using a 2.38% by mass aqueous tetramethylammonium hydroxide (TMAH) solution, washed with water, and dried, thereby affording a substrate on which a 200 nm-pitch line-and-space resist pattern with a line width of the line pattern of 30 nm to 100 nm was formed.

A silicon-containing film was etched using the resist pattern as a mask and using the aforementioned etching apparatus under the conditions of CF₄=200 sccm, PRESS.=85 mT, HF RF (high-frequency power for plasma generation)=500 W, LF RF (high-frequency power for bias)=0 W, DCS=−150 V, and RDC (gas center flow ratio)=50%, thereby affording a substrate on which a pattern was formed on the silicon-containing film. Subsequently, the resist underlayer film was etched using the silicon-containing film pattern as a mask and using the aforementioned etching apparatus under the conditions of O₂=400 sccm, PRESS.=25 mT, HF RF (high-frequency power for plasma generation)=400 W, LF RF (high-frequency power for bias)=0 W, DCS=0 V, and RDC (gas center flow ratio)=50%, thereby affording a substrate on which a pattern was formed on the resist underlayer film. A silicon dioxide film was etched using the resist underlayer film pattern as a mask and using the aforementioned etching apparatus under the conditions of CF₄=180 sccm, Ar=360 sccm, PRESS.=150 mT, HF RF (high-frequency power for plasma generation)=1,000 W, LF RF (high-frequency power for bias)=1,000 W, DCS=−150 V, RDC (gas center flow ratio)=50%, and 60 seconds, thereby affording a substrate on which a pattern was formed on the silicon dioxide film.

Thereafter, for the substrate on which a pattern was formed on a silicon dioxide film, an image was obtained by enlarging the shape of the resist underlayer film pattern of each line width by a magnification of 250,000 times with a scanning electron microscope (“CG-4000” manufactured by Hitachi High-Technologies Corporation), and then the image was subjected to image processing. Thereby, as shown in the FIGURE, for the lateral side surface 3a of the resist underlayer film pattern 3 (line pattern) having a length of 1,000 nm, a value of 3 sigma, which was obtained by multiplying a standard deviation by 3, the standard deviation having been calculated from the positions Xn (n=1 to 10) in the line width direction measured at 10 points at intervals of 100 nm and the position Xa of the average value of those positions in the line width direction, was defined as LER (line edge roughness). The LER, which indicates the degree of bending of a resist underlayer film pattern, increases as the line width of the resist underlayer film pattern decreases. The bending resistance was evaluated as “A” (good) when the line width of the film pattern having an LER of 5.5 nm was less than 40.0 nm, “B” (slightly good) when the line width was 40.0 nm or more and less than 45.0 nm, and “C” (poor) when the line width was 45.0 nm or more. In the FIGURE, the degree of bending of a film pattern is illustrated with exaggeration than actual one.

TABLE 2

| | Composition | Solubility | Bending resistance |
|---|---|---|---|
| Example 1 | J-1 | A | A |
| Example 2 | J-2 | A | A |
| Example 3 | J-3 | A | A |
| Example 4 | J-4 | A | A |
| Example 5 | J-5 | A | A |
| Example 6 | J-6 | A | A |
| Example 7 | J-7 | A | A |
| Example 8 | J-8 | A | A |
| Example 9 | J-9 | A | A |
| Example 10 | J-10 | A | A |
| Example 11 | J-11 | A | A |
| Example 12 | J-12 | A | A |
| Example 13 | J-13 | A | A |
| Example 14 | J-14 | A | A |
| Example 15 | J-15 | A | B |
| Example 16 | J-16 | A | B |
| Example 17 | J-17 | A | B |
| Example 18 | J-18 | A | B |
| Comparative | CJ-1 | A | C |
| Example 1 | | | |
| Comparative | CJ-2 | B | B |
| Example 2 | | | |

As can be seen from the results in Table 2, the resist underlayer films formed from the compositions of Examples were superior in solubility and bending resistance to the resist underlayer films formed from the compositions of Comparative Examples.

According to the method for manufacturing a semiconductor substrate of the present disclosure, a well-patterned substrate can be obtained with a high yield. The composition of the present disclosure can form a resist underlayer film excellent in solubility and bending resistance. Therefore, they can suitably be used for, for example, producing semiconductor devices expected to be further microfabricated in the future.

Obviously, numerous modifications and variations of the present invention(s) are possible in light of the above teachings. It is therefore to be understood that within the scope of the appended claims, the invention(s) may be practiced otherwise than as specifically described herein.

What is claimed is:

1. A method for manufacturing a semiconductor substrate, the method comprising:
forming a resist underlayer film directly or indirectly on a substrate by applying a composition for forming a resist underlayer film;
forming a resist pattern directly or indirectly on the resist underlayer film formed; and
performing etching using the resist pattern as a mask, wherein
the composition for forming a resist underlayer film comprises:
a compound comprising a nitro group; and
a solvent, wherein
the compound comprising a nitro group is a polymer comprising a repeating unit which comprises a nitro group and an aromatic ring, an aromatic ring-containing compound comprising a nitro group and an aromatic ring, and having a molecular weight of 600 or more and 3,000 or less, or a combination thereof, and
a content of the compound comprising a nitro group in the composition for forming a resist underlayer film relative to total components other than the solvent in the composition for forming a resist underlayer film is 10% by mass or more.

2. The method according to claim 1, wherein the polymer is a polymer comprising a repeating unit represented by formula (1): 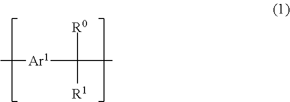
wherein, in the formula (1), Ar¹ is a divalent group having an aromatic ring having 5 to 40 ring atoms; and R⁰ is a hydrogen atom or a monovalent organic group having 1 to 40 carbon atoms, R¹ is a monovalent organic group having 1 to 40 carbon atoms, or R⁰ and R¹ taken together represent a ring structure, and at least one selected from the group consisting of Ar¹, R⁰ and R¹ comprises a nitro group.

3. The method according to claim 2, wherein R¹ is a monovalent group comprising an aromatic ring having 5 to 40 ring members.

4. The method according to claim 1, wherein the aromatic ring is at least one aromatic hydrocarbon ring selected from the group consisting of a benzene ring, a naphthalene ring, an anthracene ring, a phenalene ring, a phenanthrene ring, a pyrene ring, a fluorene ring, and a perylene ring.

5. The method according to claim 1, wherein the compound comprising a nitro group comprises at least one group selected from the group consisting of a hydroxy group, a group represented by formula (2-1), and a group represented by formula (2-2): 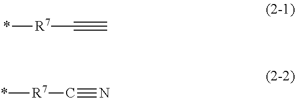
wherein, in the formulas (2-1) and (2-2), each R⁷ is independently a divalent organic group having 1 to 20 carbon atoms or a single bond; and * is a bond with a carbon atom in the aromatic ring.

6. The method according to claim 1, further comprising forming a silicon-containing film directly or indirectly on the resist underlayer film before forming the resist pattern.

7. A composition comprising:
a compound comprising a nitro group; and
a solvent, wherein
the compound comprising a nitro group is a polymer comprising a repeating unit which comprises a nitro group and an aromatic ring, an aromatic ring-containing compound comprising a nitro group and an aromatic ring, and having a molecular weight of 600 or more and 3,000 or less, or a combination thereof, and
a content ratio of the compound comprising a nitro group in the composition relative to total components other than the solvent in the composition is 10% by mass or more.

8. The composition according to claim 7, wherein the polymer is a polymer comprising a repeating unit represented by formula (1): 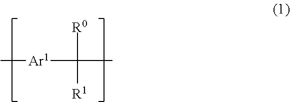
wherein, in the formula (1), Ar¹ is a divalent group having an aromatic ring having 5 to 40 ring atoms; and R⁰ is a hydrogen atom or a monovalent organic group having 1 to 40 carbon atoms, R¹ is a monovalent organic group having 1 to 40 carbon atoms, or R⁰ and R¹ taken together represent a ring structure, and at least one selected from the group consisting of Ar¹, R⁰ and R¹ has a nitro group.

9. The composition according to claim 8, wherein R¹ is a monovalent group comprising an aromatic ring having 5 to 40 ring members.

10. The composition according to claim 7, wherein the aromatic ring is at least one aromatic hydrocarbon ring selected from the group consisting of a benzene ring, a naphthalene ring, an anthracene ring, a phenalene ring, a phenanthrene ring, a pyrene ring, a fluorene ring, and a perylene ring.

11. The composition according to claim 7, wherein the compound comprising a nitro group comprises at least one group selected from the group consisting of a hydroxy group, a group represented by formula (2-1), and a group represented by formula (2-2): 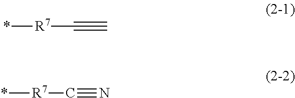
wherein, in the formulas (2-1) and (2-2), each R⁷ is independently a divalent organic group having 1 to 20 carbon atoms or a single bond; and * is a bond with a carbon atom in the aromatic ring.

12. The composition according to claim 7, which is suitable for forming a resist underlayer film.
